(19) United States
(12) Patent Application Publication
(10) Pub. No.: US 2026/0367514 A1
(43) Pub. Date: Nov. 19, 2026

(54) RADIATION-SENSITIVE COMPOSITION, COMPOSITION, METHOD FOR FORMING PATTERN, AND COMPOUND

(71) Applicant: JSR CORPORATION, Tokyo (JP)

(72) Inventors: Fuyuki EGAWA, Tokyo (JP); Kota FURUICHI, Tokyo (JP); Satoshi OKAZAKI, Tokyo (JP); Kouya UEKUSA, Tokyo (JP); Ryuichi NEMOTO, Tokyo (JP)

(73) Assignee: JSR CORPORATION, Tokyo (JP)

(21) Appl. No.: 19/710,643

(22) Filed: Jun. 17, 2026

Related U.S. Application Data
(63) Continuation-in-part of application No. PCT/JP2024/041401, filed on Nov. 22, 2024.

(30) Foreign Application Priority Data
Dec. 19, 2023 (JP) 2023-214162

(51) Int. Cl. G03F 7/039; C08F 220/18; C08L 33/14; G03F 7/004; G03F 7/038; G03F 7/20

(52) U.S. Cl. CPC G03F 7/039; C08F 220/1809; C08L 33/14; G03F 7/0045; G03F 7/0046; G03F 7/038; G03F 7/2004

(57) ABSTRACT

A radiation-sensitive composition includes: a first polymer including a structural unit (I) which includes an acid-dissociable group; a second polymer including a structural unit (i) derived from a compound represented by formula (F1); and a solvent. W is a polymerizable group; L is a single bond or an (n+1)-valent linking group; R¹ is a divalent hydrocarbon group having 1 to 10 carbon atoms; X¹, X², and X³ are each independently a hydrogen atom or a fluorine atom; at least one selected from the group consisting of X¹, X², and X³ is a fluorine atom; n is an integer of 1 to 3; n is 1 when L is a single bond; and a plurality of R¹s, X¹s, X²s, or X³s are same as or different from each other when n is 2 or more.

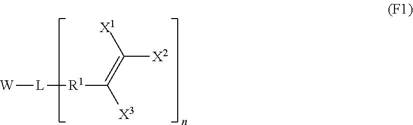

### CROSS-REFERENCE TO RELATED APPLICATIONS

The present application is a continuation-in-part application of International Patent Application No. PCT/JP2024/041401 filed Nov. 22, 2024, which claims priority to Japanese Patent Application No. 2023-214162 filed Dec. 19, 2023. The contents of these applications are incorporated herein by reference in their entirety.

### BACKGROUND OF THE DISCLOSURE

### Technical Field

The present disclosure relates to a radiation-sensitive composition, a composition, a method for forming a pattern, and a compound.

### Background Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a polymer into a developer such as an alkaline or organic solvent between an exposed part and a non-exposed part.

In the photolithography technique, pattern miniaturization is promoted by using short-wavelength radiation such as ArF excimer laser, or by combining such radiation with an immersion exposure method (liquid immersion lithography). As a next-generation technology, lithography using shorter wavelength radiation such as electron beams, X-rays and EUV (extreme ultraviolet rays) is also being utilized.

In order to improve process efficiency by surface modification of a resist film in parallel with shortening of the radiation wavelength, a technique of adding a hydrophobic resin as a surface modifier to a resist composition has been proposed in addition to a technique of providing a liquid immersion upper film having high water repellency on a surface of a resist film (Japanese Patent No. 6774214).

### SUMMARY

According to an aspect of the present disclosure, a radiation-sensitive composition includes: a first polymer including a structural unit (I) which includes an acid-dissociable group; a second polymer including a structural unit (i) derived from a compound represented by formula (F1); and a solvent.

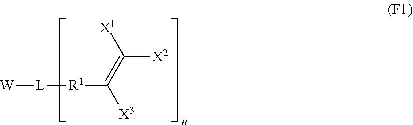

In the formula (F1), W is a polymerizable group; L is a single bond or an (n+1)-valent linking group; R¹ is a divalent hydrocarbon group having 1 to 10 carbon atoms; X¹, X², and X³ are each independently a hydrogen atom or a fluorine atom; at least one selected from the group consisting of X¹, X², and X³ is a fluorine atom; n is an integer of 1 to 3; n is 1 when L is a single bond; and a plurality of R¹s, X¹s, X²s, or X³s are same as or different from each other when n is 2 or more.

According to an aspect of the present disclosure, a composition includes: a second polymer including a structural unit (i) derived from a compound represented by formula (F1); and a solvent.

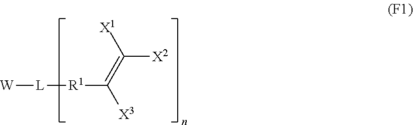

In the formula (F1), W is a polymerizable group; L is a single bond or an (n+1)-valent linking group; R¹ is a divalent hydrocarbon group having 1 to 10 carbon atoms; X¹, X², and X³ are each independently a hydrogen atom or a fluorine atom; at least one selected from the group consisting of X¹, X², and X³ is a fluorine atom; n is an integer of 1 to 3; n is 1 when L is a single bond; and a plurality of R¹s, X¹s, X²s, or X³s are same as or different from each other when n is 2 or more.

According to an aspect of the present disclosure, a method for forming a pattern includes: applying the above-described radiation-sensitive composition directly or indirectly to a substrate to form a resist film; exposing the resist film to light; and developing the exposed resist film.

According to an aspect of the present disclosure, a method for forming a pattern includes: directly or indirectly applying a radiation-sensitive composition to a substrate to form a resist film; applying the above-described composition to the resist film to form a liquid immersion upper film; subjecting the resist film provided with the liquid immersion upper film to immersion exposure; and developing the resist film subjected to the immersion exposure.

According to an aspect of the present disclosure, a compound includes: a polymerizable group; and a partial structure represented by formula (a).

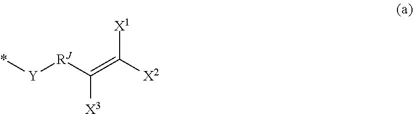

In the formula (a), Y is a divalent heteroatom-containing group or a divalent linking group having three or more carbon atoms; R^{J} is a divalent hydrocarbon group having one or two carbon atoms; X¹, X², and X³ are each independently a hydrogen atom or a fluorine atom; at least one selected from the group consisting of X¹, X², and X³ is a fluorine atom; and*is a bond to an atom of a portion other than the partial structure in the compound.

### DESCRIPTION OF EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed.

Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Due to the recent increase in environmental awareness, there is an increasing demand for reducing fluorine also in surface modifiers that often use fluorine atoms. Even in such a resist composition or composition for forming a liquid immersion upper film in which fluorine of a surface modifier is reduced, various resist performances equivalent to or higher than conventional performances are required in terms of sensitivity, critical dimension uniformity (CDU) that is an index of uniformity of a line width and a hole diameter, line width roughness (LWR) indicating variation in a line width or a line width of a resist pattern, water repellency, the development defect-inhibiting properties, and the like.

The radiation-sensitive composition of the present disclosure can exhibit excellent sensitivity, CDU, LWR, water repellency, and the development defect-inhibiting properties in pattern formation. The reason for this is not clear, but the following reason is conceivable, without being limited thereto. The second polymer can exhibit high water repellency and localization on the surface due to the fluorine atoms contained in the structural unit (i). This makes it possible to suppress transfer of water-soluble components such as generated acids to the immersion liquid and intermixing at the surface layer, and to exhibit good sensitivity, CDU, and LWR. In addition, in a fluorinated vinyl structure at the terminal of the structural unit (i), the surface free energy is equal to or smaller than that of the conventional perfluoro structure, and the localization on the surface of the resist film is improved. This makes it possible to improve the solubility in an alkaline developer as compared with the conventional case while exhibiting equivalent water repellency even with a smaller fluorine number than the conventional case, and as a result, it is possible to reduce development defects. It is presumed that various resist performances can be exerted due to synergistic action of these factors.

According to the composition for forming a liquid immersion upper film of the present disclosure, it is possible to form a liquid immersion upper film having high water repellency due to the polymer containing the structural unit (i). This makes it possible to suppress transfer of water-soluble components such as generated acids to the immersion liquid and intermixing at the surface layer, and to exhibit good sensitivity, CDU, and LWR. In addition, in the fluorinated vinyl structure at the terminal of the structural unit (i), the surface free energy is equal to or smaller than that of the conventional perfluoro structure, and the solubility in an alkaline developer can be improved as compared with the conventional case while exhibiting equivalent water repellency even with a smaller fluorine number than that in the conventional case, and as a result, development defects can be reduced. It is presumed that various resist performances can be exerted due to synergistic action of these factors.

In the method for forming a pattern of the present disclosure, the resist film or the liquid immersion upper film having excellent sensitivity, CDU, LWR, water repellency, and development defect-inhibiting properties, or the radiation-sensitive composition or the composition for forming a liquid immersion upper film capable of forming a pattern is used, and therefore a high-quality resist pattern can be efficiently formed.

Since the compound of the present disclosure can exhibit good water repellency and solubility due to the partial structure, when the compound is incorporated into a polymer of a radiation-sensitive composition, the polymer can exhibit excellent sensitivity, CDU, LWR, water repellency, and development defect-inhibiting properties when a resist pattern is formed.

The embodiments of the present invention will be described in detail below, but the present invention is not limited to these embodiments. Preferred combinations of embodiments are also preferred.

### First Embodiment

### <Radiation-Sensitive Composition>

A radiation-sensitive composition (hereinafter also simply referred to as “composition”) according to the present embodiment contains a first polymer, a second polymer, and a solvent. The radiation-sensitive composition further contains a radiation-sensitive acid generator and an acid diffusion controlling agent, as necessary. The composition may contain other optional components as long as the effects of the present disclosure are not impaired.

### (First Polymer)

The first polymer (hereinafter also simply referred to as “base polymer”) is an aggregate of polymers having a structural unit (hereinafter, also referred to as “structural unit (I)”) containing an acid-dissociable group. The “acid-dissociable group” refers to a group that substitutes for a hydrogen atom of a carboxy group, a phenolic hydroxyl group, an alcoholic hydroxyl group, a sulfo group, or the like, and is dissociated by the action of an acid. The radiation-sensitive composition is excellent in pattern-forming performance because the polymer has the structural unit (I).

In addition to the structural unit (I), the base polymer preferably has a structural unit (II) containing at least one selected from the group consisting of a lactone structure, a cyclic carbonate structure, and a sultone structure described later, and may have another structural unit other than the structural units (I) and (II). Each of the structural units will be described below.

### [Structural Unit (I)]

The structural unit (I) contains an acid-dissociable group. The structural unit (I) is not particularly limited as long as it contains an acid-dissociable group. Examples of such a structural unit (I) include a structural unit having a tertiary alkyl ester moiety, a structural unit having a structure obtained by substituting the hydrogen atom of a phenolic hydroxyl group with a tertiary alkyl group, and a structural unit having an acetal bond. From the viewpoint of improving the pattern-forming performance of the radiation-sensitive composition, a structural unit represented by the formula (3) (hereinafter also referred to as a “structural unit (I-1)”) is preferred.

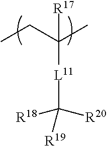

In the formula (3), R¹⁷ is a hydrogen atom, a fluorine atom, a methyl group, or a trifluoromethyl group. R¹⁸ is a monovalent hydrocarbon group having 1 to 20 carbon atoms. R¹⁹ and R²⁰ are each independently a monovalent chain hydrocarbon group having 1 to 10 carbon atoms or a monovalent alicyclic hydrocarbon group having 3 to 20 carbon atoms, or R¹⁹ and R²⁰ taken together represent a divalent alicyclic group having 3 to 20 carbon atoms together with a carbon atom to which R¹⁹ and R²⁰ are bonded. L¹¹ represents *—COO—, *—L^{11a}COO—, or *—COOL^{11a}COO—. L^{11a} is a substituted or unsubstituted alkanediyl group or arenediyl group. * is a bond to a carbon atom to which R¹⁷ is bonded.

From the viewpoint of copolymerizability of a monomer that will give the structural unit (I-1), R⁵¹ is preferably a hydrogen atom or a methyl group, more preferably a methyl group.

Examples of the alkanediyl group represented by L^{11a} include alkanediyl groups having 1 to 10 carbon atoms such as a methylene group, an ethanediyl group, a 1,3-propanediyl group, and a 2,2-propanediyl group. L^{11a} is preferably a methylene group or an ethanediyl group.

Examples of the arenediyl group represented by L^{11a} include divalent aromatic hydrocarbon groups having 6 to 20 carbon atoms such as a benzenediyl group and a naphthalenediyl group. As L^{11a}, a benzenediyl group is preferable.

Examples of the substituent that can be possessed by the arenediyl group represented by L^{11a} include a halogen atom, a hydroxy group, a carboxy group, a cyano group, a nitro group, an alkyl group, a fluorinated alkyl group, an alkoxycarbonyloxy group, an acyl group, an acyloxy group, and an alkoxy group.

Examples of the monovalent hydrocarbon group having 1 to 20 carbon atoms represented by R¹⁸ include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon groups having 1 to 10 carbon atoms represented by R¹⁸ to R²⁰ include a monovalent linear or branched saturated hydrocarbon group having 1 to 10 carbon atoms or a monovalent linear or branched unsaturated hydrocarbon group having 1 to 10 carbon atoms.

Examples of the monovalent alicyclic hydrocarbon groups having 3 to 20 carbon atoms represented by R¹⁸ to R²⁰ above include monocyclic or polycyclic saturated hydrocarbon groups and monocyclic or polycyclic unsaturated hydrocarbon groups. As the monocyclic saturated hydrocarbon group, a cyclopentyl group, a cyclohexyl group, a cycloheptyl group, and a cyclooctyl group are preferable. As the polycyclic cycloalkyl group, bridged alicyclic hydrocarbon groups such as a norbornyl group, a bornyl group, an adamantyl group, a tricyclodecyl group, and a tetracyclododecyl group are preferable. Examples of the monocyclic unsaturated hydrocarbon group include monocyclic cycloalkenyl groups such as a cyclopropenyl group, a cyclobutenyl group, a cyclopentenyl group, and a cyclohexenyl group. Examples of the polycyclic unsaturated hydrocarbon group include polycyclic cycloalkenyl groups such as a norbornenyl group, a tricyclodecenyl group, and a tetracyclododecenyl group. The bridged alicyclic hydrocarbon group refers to a polycyclic alicyclic hydrocarbon group in which two carbon atoms that compose an alicyclic ring and are not adjacent to each other are bonded by a linking group containing one or more carbon atoms.

Examples of the monovalent aromatic hydrocarbon group having 6 to 20 carbon atoms represented by R¹⁸ above include aryl groups such as a phenyl group, a tolyl group, a xylyl group, a naphthyl group, and an anthryl group; and aralkyl groups such as a benzyl group, a phenethyl group, and a naphthylmethyl group.

R¹⁸ is preferably a linear or branched saturated hydrocarbon group having 1 to 10 carbon atoms or an alicyclic hydrocarbon group having 3 to 20 carbon atoms.

The divalent alicyclic group having 3 to 20 carbon atoms formed by R¹⁹ and R²⁰ taken together with the carbon atom to which R¹⁹ and R²⁰ are bonded is not particularly limited as long as it is a group obtained by removing two hydrogen atoms from the same carbon atom constituting a carbon ring of a monocyclic or polycyclic alicyclic hydrocarbon having the above-described carbon number. The divalent alicyclic group having 3 to 20 carbon atoms may either be a monocyclic hydrocarbon group or a polycyclic hydrocarbon group. The polycyclic hydrocarbon group may either be a bridged alicyclic hydrocarbon group or a condensed alicyclic hydrocarbon group and may either be a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

When the monocyclic alicyclic hydrocarbon group is a saturated hydrocarbon group, preferred examples thereof include a cyclopentanediyl group, a cyclohexanediyl group, a cycloheptanediyl group, and a cyclooctanediyl group. When the monocyclic alicyclic hydrocarbon group is an unsaturated hydrocarbon group, preferred examples thereof include a cyclopentenediyl group, a cyclohexenediyl group, a cycloheptenediyl group, a cyclooctenediyl group, and a cyclodecenediyl group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group).

Among them, it is preferable that R¹⁸, R¹⁹, and R²⁰ be each independently an alkyl group having 1 to 4 carbon atoms, or R¹⁸ be an alkyl group having 1 to 4 carbon atoms and that the alicyclic structure composed of R¹⁹ and R²⁰ combined with each other together with a carbon atom to which R¹⁹ and R²⁰ are bonded be a polycyclic or monocyclic cycloalkane structure.

Examples of the structural unit (I-1) include structural units represented by the formulas (3-1) to (3-15) (hereinafter also referred to as “structural units (I-1-1) to (I-1-15)”).

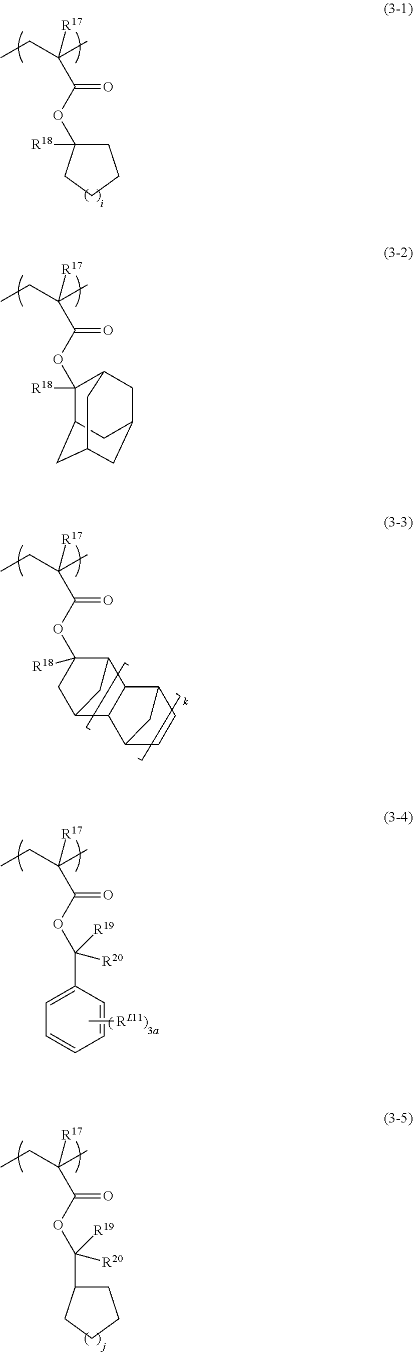

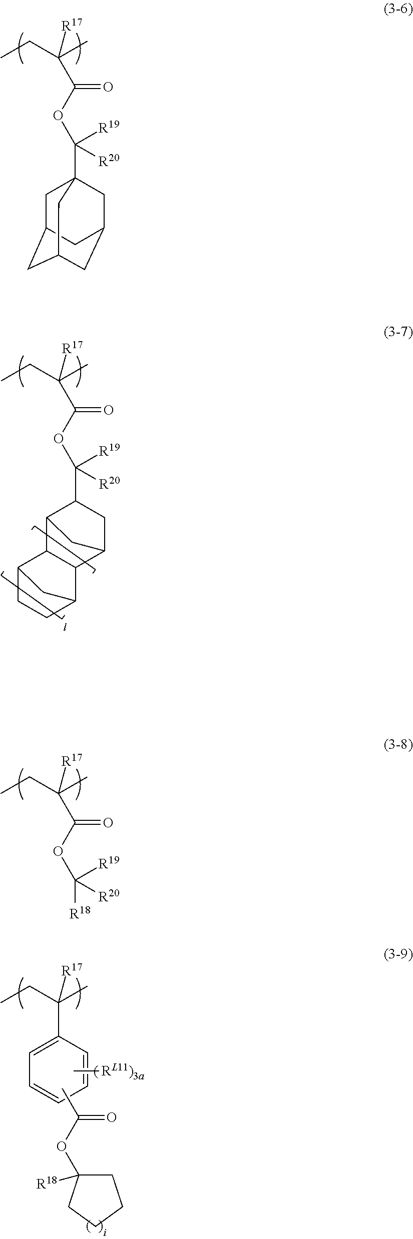

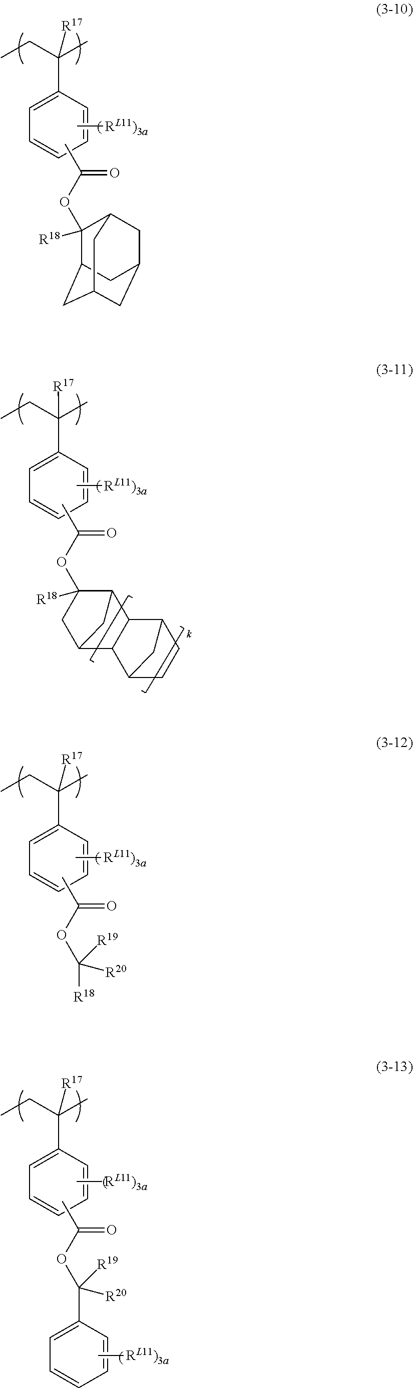

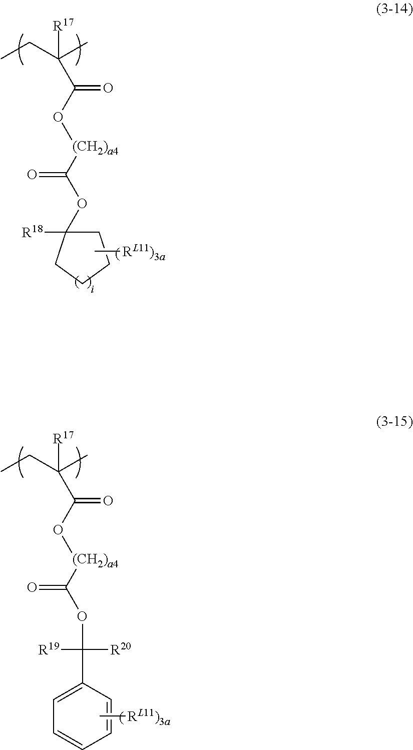

In the formulas (3-1) to (3-15), R¹⁷ to R²⁰ have the same meaning as in the formula (3). R^{L11} is a halogen atom, a hydroxy group, a carboxy group, a cyano group, a nitro group, an alkyl group, a fluorinated alkyl group, an alkoxycarbonyloxy group, an acyl group, an acyloxy group, or an alkoxy group. i and j are each independently an integer of 1 to 4. k and 1 are each 0 or 1. 3a's are each independently an integer of 0 to 3. When 3a is 2 or more, a plurality of R^{L11}s are the same as or different from each other. a4 is an integer of 1 to 3.

As i and j, 1 is preferable. R¹⁸ is preferably a methyl group, an ethyl group, an isopropyl group, a t-butyl group, a cyclopentyl group, an ethenyl group, a phenyl group, or an iodophenyl group. As R¹⁹ and R²⁰, a methyl group, and an ethyl group are preferable. By employing an iodine atom as R^{L11}, an iodo group can be suitably introduced into the structural unit (I).

Furthermore, the polymer may contain structural units represented by formulas (1f) to (2f) as the structural unit (I).

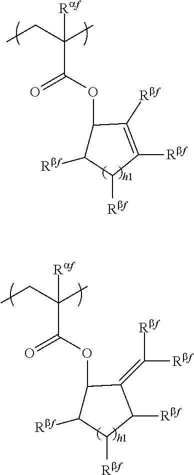

In the formulas (1f) to (2f), R^{αf}s are each independently a hydrogen atom, a fluorine atom, a methyl group, or a trifluoromethyl group. R^{βf}s are each independently a hydrogen atom or a chain alkyl group having 1 to 5 carbon atoms. h1 is an integer of 1 to 4.

As the R^{βf}, a hydrogen atom, a methyl group, or an ethyl group is preferable. h1 is preferably 1 or 2.

The base polymer may contain one type or a combination of two or more types of the structural units (I).

The lower limit of the content by percent of the structural unit (I) (a total content by percent when a plurality of types are contained) is preferably 20 mol %, more preferably 30 mol %, and still more preferably 35 mol % based on all structural units constituting the base polymer. The upper limit of the content by percent is preferably 80 mol %, more preferably 70 mol %, and still more preferably 65 mol %. When the content of the structural unit (I) is set to fall within the above range, the pattern-forming performance of the radiation-sensitive composition can further be improved.

### [Structural Unit (II)]

The structural unit (II) is a structural unit including at least one selected from the group consisting of a lactone structure, a cyclic carbonate structure and a sultone structure. The solubility of the base polymer into a developer can be adjusted by further introducing the structural unit (II). As a result, the radiation-sensitive composition can provide improved lithography properties such as the resolution. The adhesion between a resist pattern formed from the base polymer and a substrate can also be improved.

Examples of the structural unit (II) include structural units represented by the formulae (T-1) to (T-11).

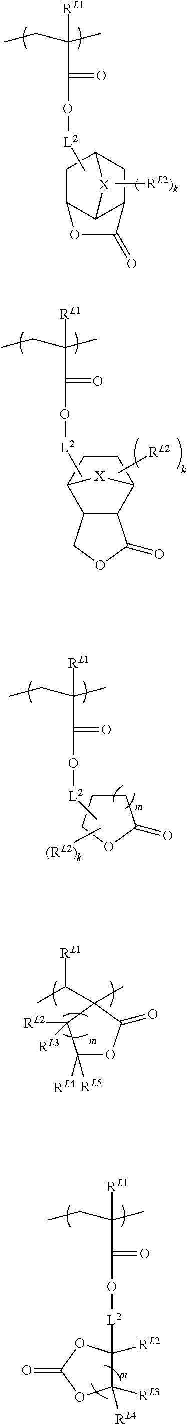

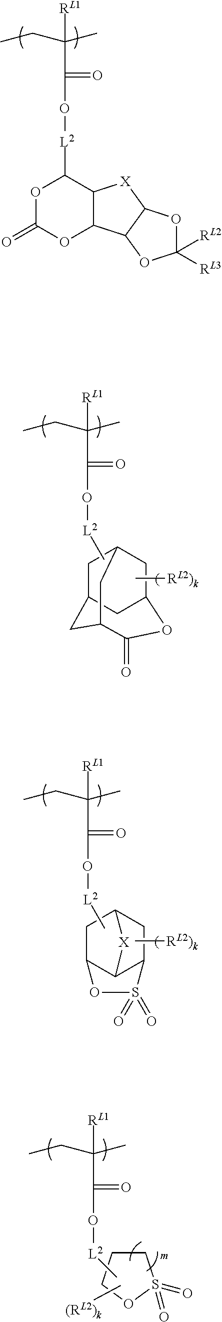

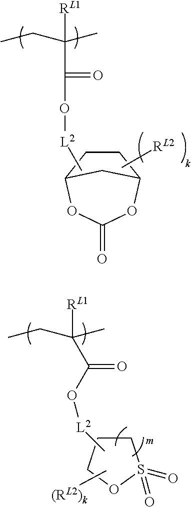

In the formulae, R^{L1} is a hydrogen atom, a fluorine atom, a methyl group, or a trifluoromethyl group; R^{L2} to R^{L5} are each independently a hydrogen atom, an alkyl group having 1 to 4 carbon atoms, a cyano group, a trifluoromethyl group, a methoxy group, a methoxycarbonyl group, a hydroxy group, a hydroxymethyl group, or a dimethylamino group; R^{L4} and R^{L5} may be a divalent alicyclic group having 3 to 8 carbon atoms, which is obtained by combining R^{L4} and R^{L5} with the carbon atom to which they are bound. L² is a single bond, or a divalent linking group; X is an oxygen atom or a methylene group; k is an integer of 0 to 3; and m is an integer of 1 to 3.

Example of the divalent alicyclic group having 3 to 8 carbon atoms, which is composed of a combination of R^{L4} and R^{L5} with the carbon atom to which they are bound, includes the divalent alicyclic group having 3 to 8 carbon atoms in the divalent alicyclic group having 3 to 20 carbon atoms, which is composed of R¹⁹ and R²⁰ in the formula (3) with the carbon atom to which they are bound. One or more hydrogen atoms on the alicyclic group may be substituted with a hydroxy group.

Examples of the divalent linking group represented by L² as described above include a divalent straight or branched chain hydrocarbon group having 1 to 10 carbon atoms; a divalent alicyclic hydrocarbon group having 4 to 12 carbon atoms; and a group composed of one or more of the hydrocarbon group thereof and at least one group of —CO—, —O—, —NH— and —S—.

Among them, the structural unit (II) is preferably a group having a lactone structure, more preferably a group having a g-butyrolactone structure or a norbornane lactone structure, and further preferably a group derived from a g-butyrolactone-yl-(meth)acrylate or a norbornane lactone-yl (meth)acrylate.

When the base polymer has the structural unit (II), the lower limit of the content by percent of the structural unit (II) (a total content by percent when a plurality of types are contained) is preferably 10 mol %, more preferably 20 mol %, and still more preferably 25 mol % based on all structural units constituting the base polymer. The upper limit of the content by percent is preferably 80 mol %, more preferably 70 mol %, and still more preferably 60 mol %. By adjusting the content by percent of the structural unit (II) within the ranges, the radiation-sensitive composition can provide improved lithography properties such as the resolution. The adhesion between the formed resist pattern and the substrate can also be improved.

### [Structural Unit (III)]

The base polymer optionally has another structural unit in addition to the structural units (I) and (II). Another structural unit includes a structural unit (III) containing a polar group (excluding those corresponding to the structural unit (II)). When the base polymer further has a structural unit (III), solubility in the developer can be adjusted. As a result, lithographic performance such as resolution of the radiation-sensitive composition can be improved. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (III) include structural units represented by the formulas.

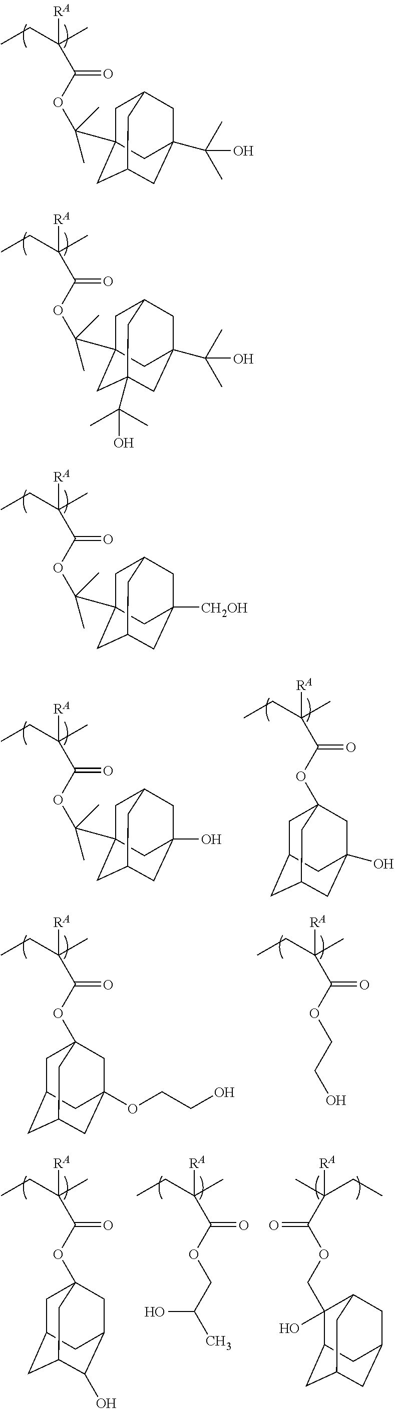

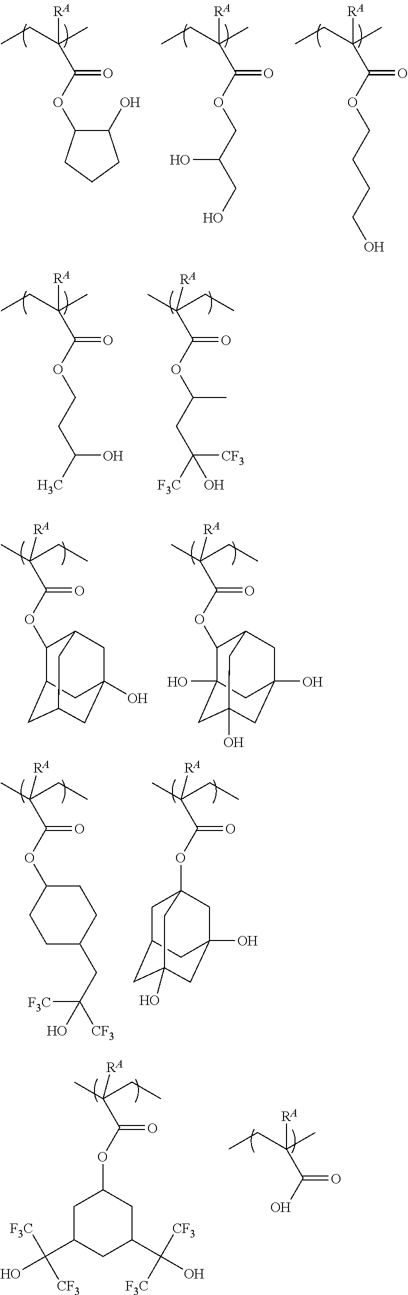

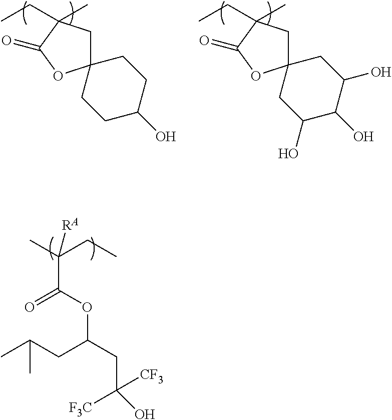

In the formulas, R^{A} is a hydrogen atom, a fluorine atom, a methyl group, or a trifluoromethyl group.

When the base polymer has the structural unit (III), the lower limit of the content by percent of the structural unit (III) (a total content by percent when a plurality of types are contained) is preferably 1 mol %, more preferably 2 mol %, and still more preferably 3 mol % based on all structural units constituting the base polymer. The upper limit of the content by percent is preferably 30 mol %, more preferably 20 mol %, and still more preferably 15 mol %. When the content of the structural unit (III) is set to fall within the above range, the radiation-sensitive composition can provide further improved lithography properties such as the resolution.

### [Structural Unit (IV)]

The base polymer optionally has, as another structural unit, a structural unit having a phenolic hydroxyl group (hereinafter also referred to as “structural unit (IV)”), in addition to the structural unit (III) having a polar group. The structural unit (IV) contributes to an improvement in etching resistance and an improvement in a difference in solubility of a developer (dissolution contrast) between an exposed part and a non-exposed part. The structural unit (IV) can be suitably applied to pattern formation using exposure with a KrF excimer laser, or a radioactive ray having a wavelength of 50 nm or less, such as an electron beam or EUV. In this case, the polymer preferably has the structural unit (I) together with the structural unit (IV).

The structural unit containing a phenolic hydroxy group is represented by, for example, the formulas (4-1) to (4-6).

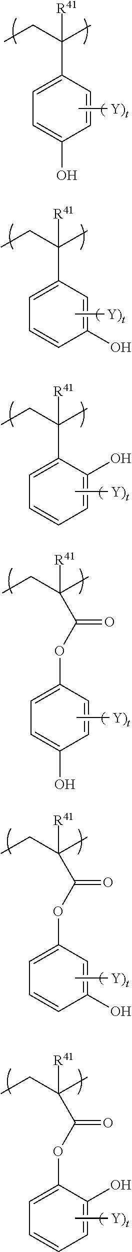

In the formulas (4-1) to (4-6), R⁴¹ is independently at each occurrence a hydrogen atom, a fluorine atom, a methyl group, or a trifluoromethyl group. Y is a halogen atom, a trifluoromethyl group, a cyano group, an alkyl or alkoxy group having 1 to 6 carbon atoms, or an acyl, acyloxy, or alkoxycarbonyl group having 2 to 7 carbon atoms. When there are a plurality of Y's, the plurality of Y's are the same or different from each other, t is an integer of 0 to 4.

When the structural unit (IV) is obtained, it is preferable that the structural unit (IV) be obtained by performing polymerization in a state where the phenolic hydroxy group of the corresponding monomer is protected with a protecting group such as an alkali-dissociable group (e.g., an acyl group) during polymerization, and then deprotecting the polymerized product by hydrolysis. The monomer may be polymerized without protecting the phenolic hydroxy group.

In the case of a polymer for exposure with a KrF excimer laser or exposure to radiation with a wavelength of 50 nm or less, the lower limit of the content ratio of the structural unit (IV) (the total content ratio when a plurality of structural units (IV) are contained) is preferably 20 mol %, more preferably 30 mol % based on all structural units composing the first polymer. The upper limit of the content ratio is preferably 80 mol %, more preferably 70 mol %.

### [Other Structural Unit]

The base polymer may contain a structural unit having an alicyclic structure represented by the formula (6) as a structural unit other than the structural units listed above.

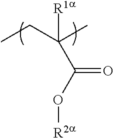

In the formula (6), R^{1α} represents a hydrogen atom, a fluorine atom, a methyl group, or a trifluoromethyl group, and R^{2α} represents a monovalent alicyclic hydrocarbon group having 3 to 20 carbon atoms.

In the formula (6), as the monovalent alicyclic hydrocarbon group having 3 to 20 carbon atoms represented by R^{2α}, the monovalent alicyclic hydrocarbon groups having 3 to 20 carbon atoms represented by R¹⁸ to R²⁰ in the formula (3) can be suitably employed.

When the base polymer contains the structural unit having the alicyclic structure, the lower limit of the content by percent of the structural unit having the alicyclic structure is preferably 2 mol %, more preferably 5 mol %, and still more preferably 8 mol % based on all structural units constituting the base polymer. The upper limit of the content by percent is preferably 30 mol %, more preferably 20 mol %, and still more preferably 15 mol %.

### Synthesis Method of Base Polymer

For example, the base polymer can be synthesized by performing a polymerization reaction of each monomer for providing each structural unit with a radical polymerization initiator or the like in a suitable solvent.

Examples of the radical polymerization initiator include an azo-based radical initiator, including azobisisobutyronitrile (AIBN), 2,2′-azobis(4-methoxy-2,4-dimethylvaleronitrile), 2,2′-azobis(2-cyclopropylpropanenitrile), 2,2′-azobis(2,4-dimethylvaleronitrile), and dimethyl 2,2′-azobisisobutyrate; and peroxide-based radical initiator, including benzoyl peroxide, t-butyl hydroperoxide, and cumene hydroperoxide. Among them, AIBN or dimethyl 2,2′-azobisisobutyrate is preferred, and AIBN is more preferred. The radical initiator may be used alone, or two or more radical initiators may be used in combination.

Examples of the solvent used for the polymerization reaction include alkanes including n-pentane, n-hexane, n-heptane, n-octane, n-nonane, and n-decane;
cycloalkanes including cyclohexane, cycloheptane, cyclooctane, decalin, and norbornane;
aromatic hydrocarbons including benzene, toluene, xylene, ethylbenzene, and cumene;
halogenated hydrocarbons including chlorobutanes, bromohexanes, dichloroethanes, hexamethylenedibromide, and chlorobenzenes;
saturated carboxylate esters, including ethyl acetate, n-butyl acetate, i-butyl acetate, and methyl propionate;
lactones such as γ-butyrolactone and δ-valerolactone;
polyhydric alcohol partial ether acetate-based solvents such as diethylene glycol mono-n-butyl ether acetate, propylene glycol monomethyl ether acetate, and dipropylene glycol monomethyl ether acetate;
ketones such as acetone, methyl ethyl ketone, 2-butanone, 4-methyl-2-pentanone, 2-heptanone, and cyclohexanone;
ethers such as tetrahydrofuran, dimethoxyethanes, diethoxyethanes, and 1,4-dioxanes; and
alcohols such as methanol, ethanol, 1-propanol, 2-propanol, 4-methyl-2-pentanol, and 1-methoxy-2-propanol. The solvents to be used in the polymerization may be used singly, or two or more thereof may be used in combination.

The reaction temperature of the polymerization reaction is typically from 40 °C to 150 °C, and preferably from 50 °C to 120 °C. The reaction time is typically from 1 hour to 48 hours, and preferably from 1 hour to 24 hours.

The molecular weight of the base polymer is not particularly limited, but the lower limit of the weight average molecular weight (Mw) as determined by Gel Permeation Chromatography (GPC) relative to standard polystyrene is preferably 3,000, more preferably 4,000, and still more preferably 5,000. The upper limit of the Mw is preferably 30,000, more preferably 20,000, and still more preferably 8,000. When the Mw of the base polymer is within the above range, the resulting resist film can obtain good heat resistance and developability.

For the base polymer, the ratio of Mw to the number average molecular weight (Mn) as determined by GPC relative to standard polystyrene (Mw/Mn) is typically 1 or more and 5 or less, preferably 1 or more and 3 or less, and more preferably 1 or more and 2 or less.

The method for measuring Mw and Mn of a polymer in the specification is as described in Examples.

The content by percent of the base polymer is preferably 50% by mass or more, more preferably 55% by mass or more, and still more preferably 60% by mass or more based on the total solid content of the radiation-sensitive composition.

### (Second Polymer)

The second polymer is a polymer containing the structural unit (i) and different from the first polymer. Since the second polymer contains the structural unit (i), the second polymer is said to be a polymer having a higher mass content of fluorine atoms than that of the first polymer as the base polymer. The second polymer may contain a structural unit other than the structural unit (i). The radiation-sensitive composition may contain one second polymer, or two or more second polymers.

### (Structural Unit (i))

The structural unit (i) is a structural unit derived from a compound represented by the formula (F1).

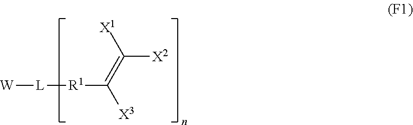

wherein, in the formula (F1),
W is a polymerizable group,
L is a single bond or an (n+1)-valent linking group,
R¹ is a divalent hydrocarbon group having 1 to 10 carbon atoms,
X¹, X², and X³ are each independently a hydrogen atom or a fluorine atom, at least one selected from the group consisting of X¹, X², and X³ is a fluorine atom,
n is an integer of 1 to 3, n is 1 when L is a single bond, and a plurality of R¹s, X¹s, X²s, or X³s are the same as or different from each other when n is 2 or more.

Examples of the polymerizable group represented by W include an ethylenically unsaturated double bond and a structure containing an ethylenically unsaturated double bond as a partial structure constituting a ring. The polymerizable group represented by W may have a substituent other than the portion bonded to L¹.

Examples of the substituent when the polymerizable group has a substituent include a halogen atom, a monovalent organic group having 1 to 20 carbon atoms, a hydroxy group, a carboxy group, a cyano group, a nitro group, and an oxo group (═O).

Note that, in the present specification, the “organic group” is a group containing at least one carbon atom. However, a functional group or a characteristic group containing a carbon atom (cyano group, carboxy group, carbonyl group, or the like) itself is not included in the organic group.

Examples of the halogen atom include a fluorine atom, a chlorine atom, a bromine atom, and an iodine atom.

Examples of the monovalent organic group having 1 to 20 carbon atoms include a monovalent hydrocarbon group having 1 to 20 carbon atoms, a group containing a divalent heteroatom-containing group between two carbon atoms of this hydrocarbon group or at the terminal of the hydrocarbon group, a group obtained by substituting some or all of the hydrogen atoms of the hydrocarbon group with a monovalent heteroatom-containing group, and a combination thereof.

As the monovalent hydrocarbon group having 1 to 20 carbon atoms in the organic group, a monovalent hydrocarbon group having 1 to 20 carbon atoms represented by R¹⁸ of the formula (3) can be suitably employed.

Examples of the divalent heteroatom-containing group include —CO—, —CS—, —NR′—, —O—, —S—, —SO₂—, and a divalent group obtained by combining them. R¹ is a hydrogen atom or a hydrocarbon group having 1 to 10 carbon atoms.

Examples of the monovalent heteroatom-containing group include a hydroxy group, a carboxy group, a sulfanyl group, a cyano group, a nitro group, and halogen atoms.

Specific examples of the polymerizable group include, but are not limited to, structures represented by the formulas below.

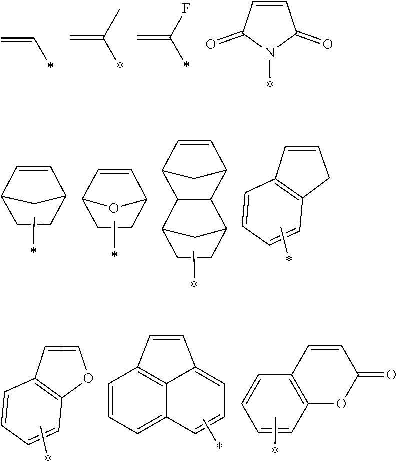

wherein * is a bond to L in the formula (F1).

As the (n+1)-valent linking group represented by L, the divalent heteroatom-containing group or a group obtained by removing n hydrogen atom(s) from the monovalent organic group having 1 to 20 carbon atoms listed as the substituent that can be included in the polymerizable group of W can be suitably employed.

The (n+1)-valent linking group represented by L preferably contains a heteroatom. The mode of containing the heteroatom in the linking group is not limited, but the heteroatom is preferably contained as the divalent heteroatom-containing group or the monovalent heteroatom-containing group, more preferably contained as the divalent heteroatom-containing group. In particular, the linking group preferably includes the divalent heteroatom-containing group at least at the terminal on the R¹ side. The same applies to the case where n is 2 or more.

L preferably includes a substituted or unsubstituted hydrocarbon structure having 1 to 15 carbon atoms. As such a hydrocarbon structure, structures corresponding to 1 to 15 carbon atoms among the monovalent hydrocarbon groups having 1 to 20 carbon atoms represented by R¹⁸ in the formula (3) can be suitably employed. The hydrocarbon structure is more preferably a chain hydrocarbon structure having 1 to 8 carbon atoms or an alicyclic hydrocarbon structure having 3 to 10 carbon atoms.

When L has a substituent, examples of the substituent include a halogen atom such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, and groups obtained by substituting a hydrogen atom on these groups with a halogen atom; a monovalent group having a lactone structure; and an oxo group (═O).

The (n+1)-valent linking group represented by L is preferably an (n+1)-valent group (hereinafter also referred to as “group (c)”) obtained by combining the substituted or unsubstituted hydrocarbon structure having 1 to 15 carbon atoms with the divalent heteroatom-containing group.

As the divalent hydrocarbon group having 1 to 10 carbon atoms represented by R¹, groups obtained by removing 1 hydrogen atom from, among the monovalent hydrocarbon groups having 1 to 10 carbon atoms represented by R¹⁸ of the formula (3), a group corresponding to 1 to 10 carbon atoms can be suitably employed.

R¹ is preferably a divalent chain hydrocarbon group having 1 to 10 carbon atoms, more preferably a divalent chain saturated hydrocarbon group having 1 to 5 carbon atoms, still more preferably a divalent linear saturated hydrocarbon group having 1 to 3 carbon atoms. Among them, R¹ is preferably a divalent hydrocarbon group having one or two carbon atoms, more preferably a methylene group or an ethanediyl group.

It is preferable that at least two selected from the group consisting of X¹, X², and X³ be fluorine atoms, and it is more preferable that all of X¹, X², and X³ be fluorine atoms.

n is preferably 1 or 2, more preferably 1.

The compound is preferably represented by the formula (f1-1) or (f1-2).

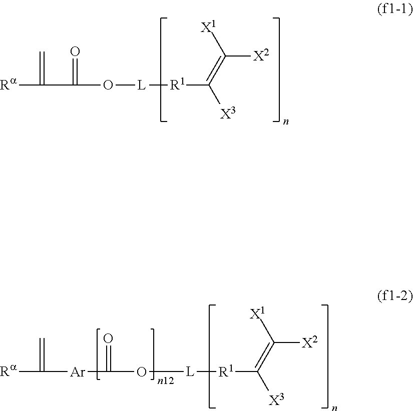

wherein, in the formulas (f1-1) and (f1-2),
R^{α} is a hydrogen atom, a halogen atom, or a monovalent organic group having 1 to 10 carbon atoms,
L, R¹, X¹, X², X³, and n have the same meaning as in the formula (F1), n is 1 when L¹¹ is a single bond, and
in the formula (f1-2),
Ar is a substituted or unsubstituted divalent aromatic ring, and
n₁₂ is 0 or 1.

As the monovalent organic group having 1 to 10 carbon atoms represented by R^{α} in the formulas (f1-1) and (f1-2), a group corresponding to 1 to 10 carbon atoms among the monovalent organic groups having 1 to 20 carbon atoms as the substituent that can be included in W above can be suitably employed.

As the (n+1)-valent linking group having one or more carbon atoms and containing a heteroatom represented by L¹¹ in the formulas (f1-1) and (f1-2), the group (ca) in L in the formula (F1) can be suitably employed.

In the formula (f1-2), examples of the aromatic ring in Ar include aromatic hydrocarbon rings such as a benzene ring, a naphthalene ring, an anthracene ring, a phenalene ring, a phenanthrene ring, a pyrene ring, a fluorene ring, a perylene ring, and a coronene ring; heteroaromatics such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine ring; and combinations thereof. The aromatic ring is preferably at least one aromatic hydrocarbon ring selected from the group consisting of a benzene ring, a naphthalene ring, an anthracene ring, a phenalene ring, a phenanthrene ring, a pyrene ring, a fluorene ring, and a perylene ring. Ar is preferably a benzene ring or a naphthalene ring, more preferably a benzene ring.

As the divalent aromatic ring represented by Ar, a group obtained by removing two hydrogen atoms from the above aromatic ring can be suitably employed.

When Ar has a substituent, the substituent when L has a substituent can be suitably employed as the substituent of Ar.

Examples of the monomer that gives the structural unit (i) include compounds represented by formulas (F1-1) to (F1-50).

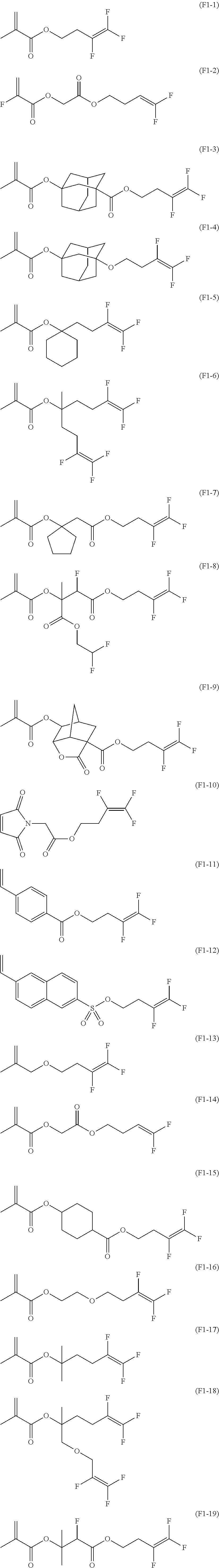

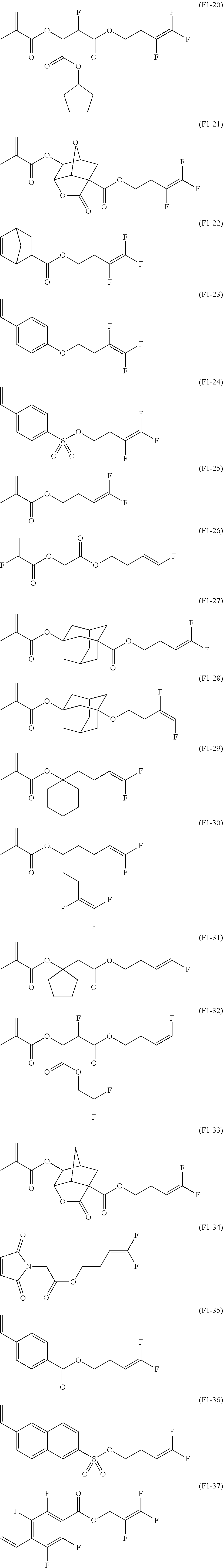

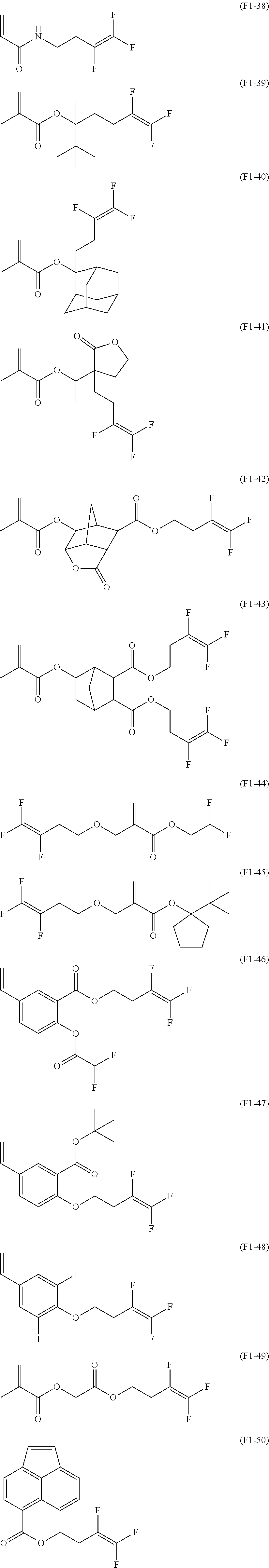

The lower limit of the content ratio of the structural unit (i) (the total content ratio when a plurality of structural units (i) are contained) is preferably 5 mol %, more preferably 15 mol %, still more preferably 20 mol % based on all structural units composing the second polymer. The upper limit of the content ratio may be 100 mol %, may be 90 mol %, may be 80 mol %, or may be 70 mol %. By setting the content ratio of the structural unit (i) within the above range, the high fluorine-content polymer can be localized in the surface layer of a resist film compared to the base polymer, which as a result makes it possible to enhance the water repellency of the surface of the resist film during immersion exposure or to perform surface modification of the resist film during EUV exposure or control of the distribution of the composition in the film.

(Method for Synthesizing Monomer Compound that Gives Structural Unit (i))

The method for synthesizing the monomer compound that gives the structural unit (i) is not particularly limited, and a known method can be adopted. Typically, the monomer compound can be produced by allowing a halogen form or alcohol form including a —CFH═CF₂ structure to react with a carboxylic acid or acid halide having a polymerizable group. An intended monomer compound can be synthesized by appropriately changing the structures of the halogen form or alcohol form including a —CFH═CF₂ structure and the carboxylic acid or acid halide having a polymerizable group.

(Structural Unit (ii))

The second polymer may contain, as another structural unit, a structural unit (ii) (except for the case corresponding to the structural unit (i)) represented by the formula (f-2). When the second polymer has the structural unit (ii), solubility in an alkaline developer is improved, and the occurrence of development defects can be suppressed.

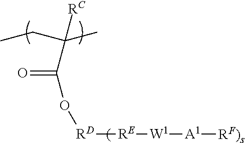

The structural unit (ii) is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{C} in the formula (f-2) is a hydrogen atom, a fluorine atom, a methyl group, or a trifluoromethyl group; R^{D} is a single bond, a hydrocarbon group having 1 to 20 carbon atoms with the valency of (s+1), a structure in which an oxygen atom, a sulfur atom, —NR^{dd}—, a carbonyl group, —COO—, —OCO—, or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having 1 to 10 carbon atoms; and s is an integer of 1 to 3.

When the structural unit (ii) has the alkali soluble group (x), R^{F} is a hydrogen atom; A¹ is an oxygen atom, —COO—* or —SO₂O—*; * refers to a bond to R^{F}; W¹ is a single bond, a hydrocarbon group having 1 to 20 carbon atoms, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{E} is a single bond, or a divalent organic group having 1 to 20 carbon atoms. When s is 2 or 3, a plurality of R^{E}, W¹, A¹ and R^{F} may be each identical or different. The affinity of the high fluorine-content polymer into the alkaline developing solution can be improved by including the structural unit (ii) having the alkali soluble group (x), and thereby prevent from generating the development defect. As the structural unit (ii) having the alkali soluble group (x), particularly preferred is a structural unit in which A¹ is an oxygen atom and W¹ is a 1,1,1,3,3,3-hexafluoro-2,2-methanediyl group.

When the structural unit (ii) has the alkali-dissociable group (y), R^{F} is a monovalent organic group having 1 to 30 carbon atoms; A¹ is an oxygen atom, —NR^{aa}—, —COO—*, —OCO—*, or —SO₂O—*; R^{aa} is a hydrogen atom, or a monovalent hydrocarbon group having 1 to 10 carbon atoms; * refers to a bond to R^{F}; W¹ is a single bond, or a divalent fluorinated hydrocarbon group having 1 to 20 carbon atoms; R^{E} is a single bond, or a divalent organic group having 1 to 20 carbon atoms. When A¹ is —COO—*, —OCO—* or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; R^{D} is a structure in which a carbonyl group is connected at the terminal on R^{E} side of the hydrocarbon group having 1 to 20 carbon atoms; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit (ii) having the alkali-dissociable group (y). As a result, the affinity of the high fluorine-content polymer into the alkaline developing solution can be significantly improved, and thereby prevent from generating the development defect more efficiently. As the structural unit (ii) having the alkali-dissociable group (y), particularly preferred is a structural unit in which A¹ is —COO—*, and R^{F} or W¹, or both is/are a group having a fluorine atom.

In terms of the copolymerizability of monomers resulting in the structural unit (ii), R^{C} is preferably a hydrogen atom or a methyl group, and more preferably a methyl group.

When the second polymer contains the structural unit (ii), the lower limit of the content ratio of the structural unit (ii) is preferably 2 mol %, more preferably 5 mol %, still more preferably 8 mol % based on all structural units composing the second polymer. The upper limit of the content ratio is preferably 30 mol %, more preferably 20 mol %, still more preferably 15 mol %. When the content ratio of the structural unit (ii) is set to fall within the above range, water repellency of a resist film during immersion exposure can be further improved, and the occurrence of development defects can be suppressed.

### [Other Structural Units]

The second polymer may contain, as a structural unit other than the structural units (i) and (ii), structural units (I), (II), and (III) in the base polymer and a structural unit having an alicyclic structure represented by the formula (6) from the viewpoint of adjusting the dissolution contrast between the exposed portion and the unexposed portion and the solubility in a developer. As the other structural unit, a structural unit containing a polyoxyalkylene alkyl ether structure can also be used. When the second polymer contains these other structural units, the content ratio of each of the other structural units can be appropriately set in the range of 1 mol % or more and 60 mol % or less. In particular, the second polymer preferably has at least one selected from the group consisting of the structural unit (ii), the structural unit (I), and the above structural unit having an alicyclic structure. In addition, it is preferable that each of the other structural units does not include a perfluoromethyl group (—CF₃) or a perfluoromethylene group (—CF₂—).

The lower limit of the Mw of the second polymer is preferably 1,000, more preferably 2,000, still more preferably 3,000. The upper limit of the Mw is preferably 30,000, more preferably 20,000, still more preferably 15,000.

The lower limit of the Mw/Mn of the second polymer is usually 1, and more preferably 1.1. In addition, the upper limit of the Mw/Mn is usually 5, preferably 3, and more preferably 2.

In the radiation-sensitive composition, the lower limit of the content of the second polymer is preferably 0.1 parts by mass, more preferably 1 part by mass, still more preferably 2 parts by mass based on 100 parts by mass of the base polymer. The upper limit of the content is preferably 30 parts by mass, more preferably 20 parts by mass, still more preferably 18 parts by mass.

### (Method for Synthesizing High Fluorine-Content Polymer)

The second polymer can be synthesized by a method similar to the above-described method for synthesizing a base polymer.

### <Radiation-Sensitive Acid Generator>

The radiation-sensitive acid generator is a component that generates an acid by exposure. The acid generated by exposure is considered to have two functions in the radiation-sensitive composition depending on the strength of the acid. A first function is, for example, a function in which the acid generated through exposure to light dissociates an acid-dissociable group of the structural unit (I) in the first polymer and generates a carboxy group or the like. The radiation-sensitive acid generator having the first function is referred to as a radiation-sensitive acid generator (I). Examples of the second function include a function that suppresses the diffusion of the acid generated from the radiation-sensitive acid generator (I) in the unexposed part without substantially dissociating the acid dissociable group of the structural unit (I) under a pattern formation condition using the radiation-sensitive composition. The radiation-sensitive acid generator having the second function is referred to as a radiation-sensitive acid generator (II). The acid generated from the radiation-sensitive acid generator (II) can be said to be relatively weaker (acid having a larger pKa) than the acid generated from the radiation-sensitive acid generator (I). Whether the radiation-sensitive acid generator functions as the radiation-sensitive acid generator (I) or the radiation-sensitive acid generator (II) depends on the energy required for dissociating the acid-dissociable group of the first polymer, the acidity of the acid generated by exposure, and the like. The containing mode of the radiation-sensitive acid generator in the radiation-sensitive composition may be a mode in which the radiation-sensitive acid generator is present alone as a compound (released from a polymer), a mode in which the radiation-sensitive acid generator is incorporated as a part of a polymer, or both of these forms, but a mode in which the radiation-sensitive acid generator is present alone as a compound is preferable.

When the radiation-sensitive composition contains the radiation-sensitive acid generator (I), the polarity of the polymer in the exposed part increases, whereby the polymer in the exposed part is soluble in the developer in the case of alkaline aqueous solution development, and is poorly soluble in the developer in the case of organic solvent development.

By containing the radiation-sensitive acid generator (II), the radiation-sensitive composition can form a resist pattern having better pattern developability, CDU and LWR.

Examples of the radiation-sensitive acid generator include an onium salt compound, a sulfonimide compound, a halogen-containing compound, and a diazoketone compound. Examples of the onium salt compound include a sulfonium salt, a tetrahydrothiophenium salt, an iodonium salt, a phosphonium salt, a diazonium salt, and a pyridinium salt. Among them, a sulfonium salt and an iodonium salt are preferable.

Examples of the acid generated by exposure include acids that generate sulfonic acid, carboxylic acid, and sulfonimide by exposure. Examples of such an acid include
(1) a compound in which a carbon atom adjacent to a sulfo group is substituted with one or more fluorine atoms, fluorinated hydrocarbon groups or cyano groups, and
(2) a compound in which a carbon atom adjacent to a sulfo group is not substituted with a fluorine atom or a fluorinated hydrocarbon group. Examples of the carboxylic acid generated by exposure include
(3) a compound in which a carbon atom adjacent to a carboxy group is substituted with one or more fluorine atoms or fluorinated hydrocarbon groups, and
(4) a compound in which a carbon atom adjacent to a carboxy group is not substituted with a fluorine atom or a fluorinated hydrocarbon group. Among them, as the radiation-sensitive acid generator (I), a radiation-sensitive acid generator corresponding to the above (1) is preferable, and a radiation-sensitive acid generator having a cyclic structure is particularly preferable. As the radiation-sensitive acid generator (II), a radiation-sensitive acid generator corresponding to the above (2), (3), or (4) is preferable, and a radiation-sensitive acid generator corresponding to the above (2) or (4) is particularly preferable. When the radiation-sensitive acid generator (II) is an onium salt compound, an intramolecular salt in which a carboxylate ion structure and an onium cation structure are covalently bonded to each other in one molecule may also be employed.

Preferably, these radiation-sensitive acid generators have one fluorine atom or one or more cyano groups substituted on the carbon atom adjacent to the sulfo group.

Examples of the radiation-sensitive acid generator include compounds represented by the formulas below.

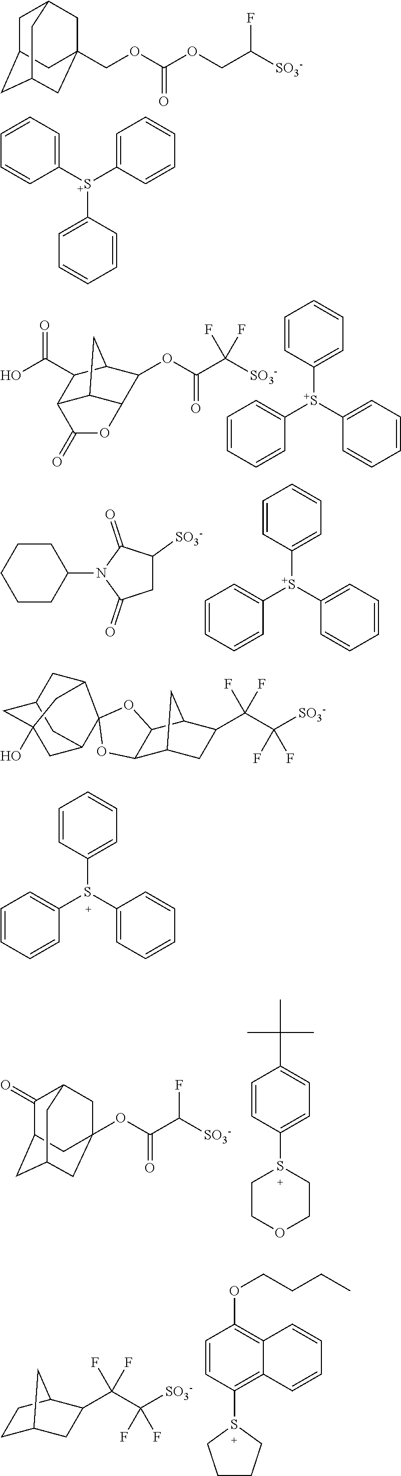

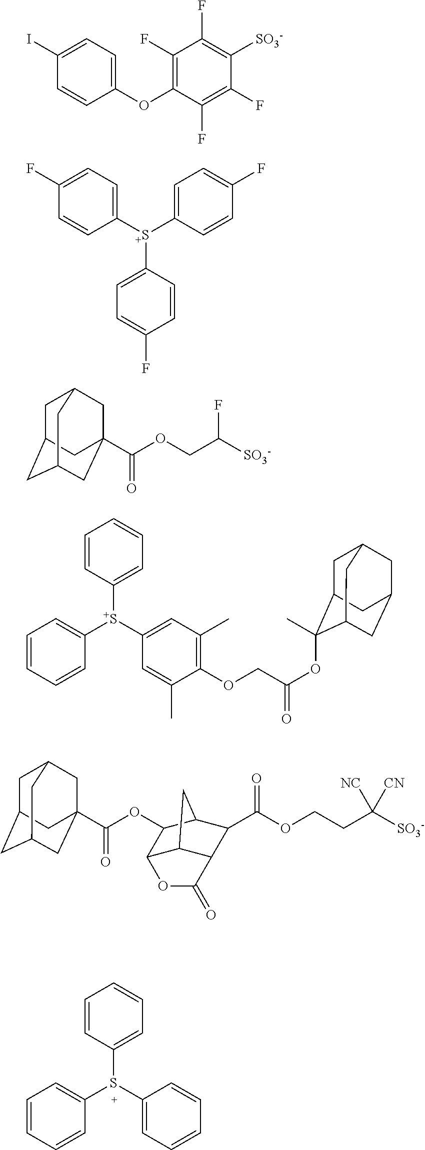

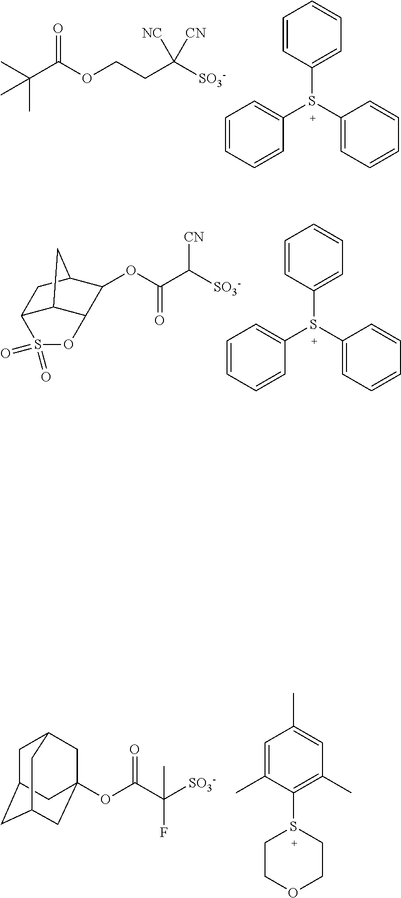

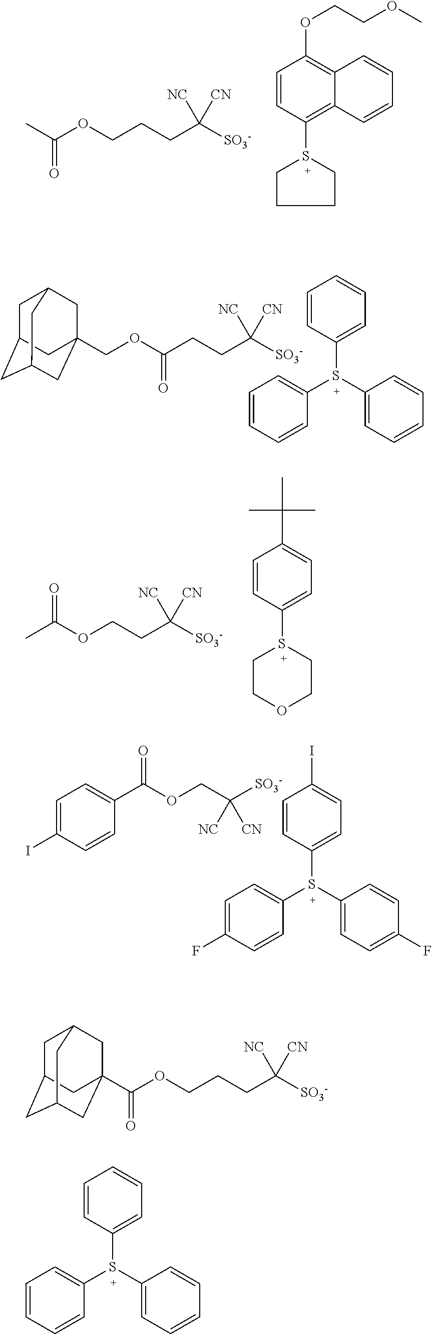

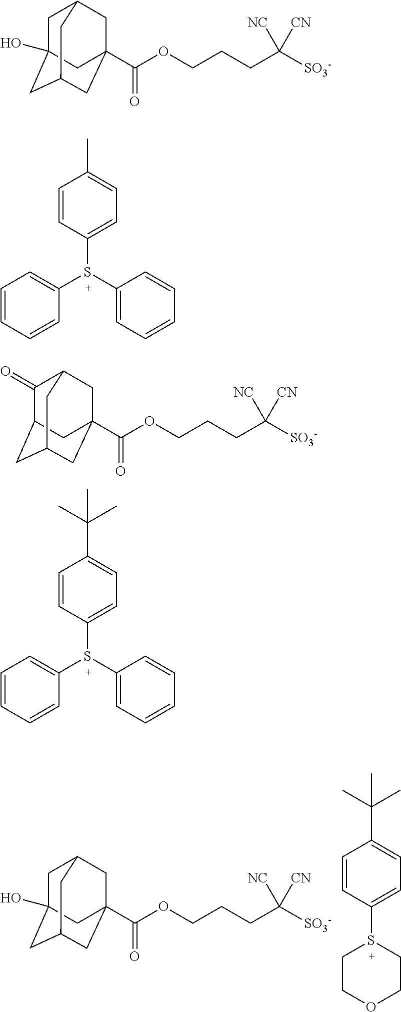

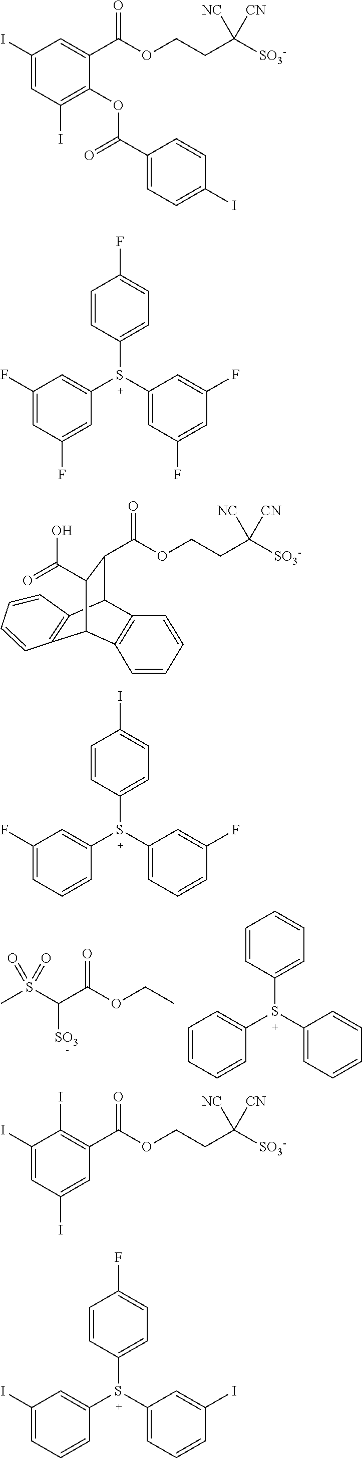

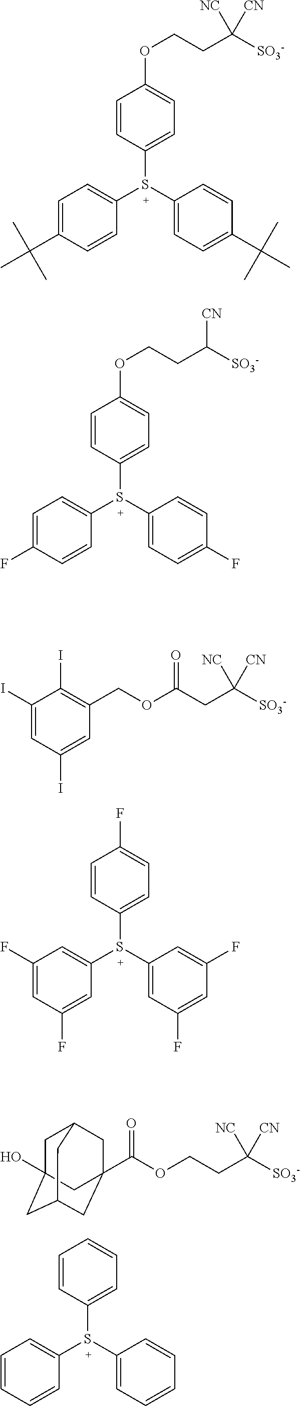

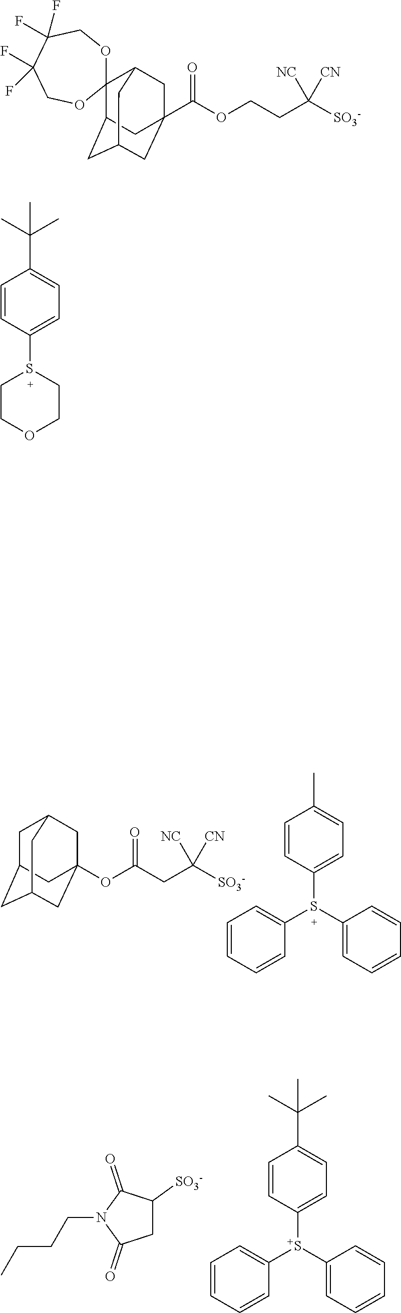

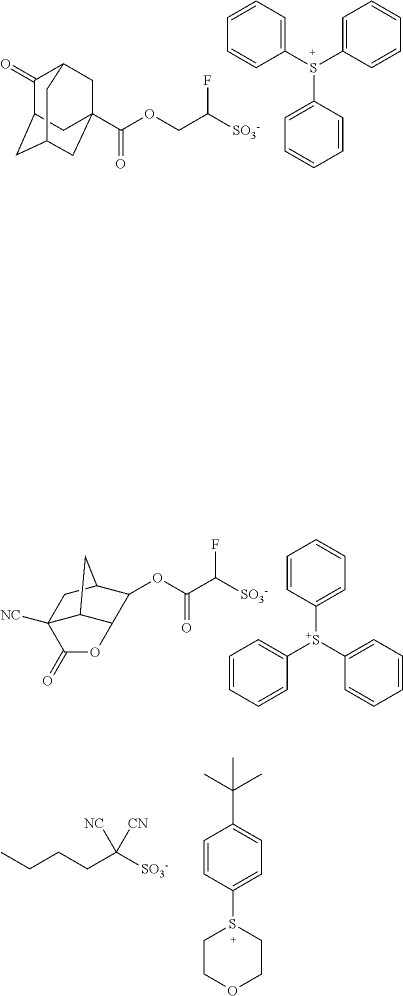

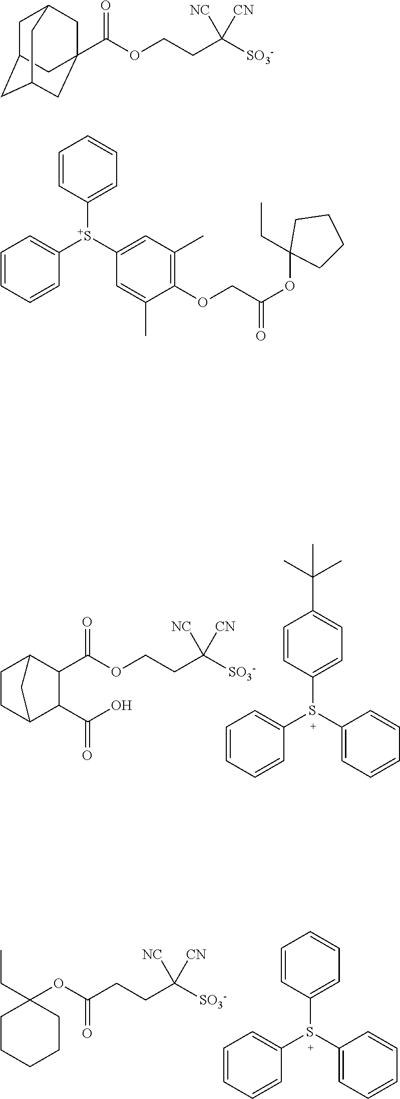

These radiation-sensitive acid generators may be used alone or in combination of two or more thereof. The lower limit of the content of the radiation-sensitive acid generator (I) (total if multiple types are included) is preferably 2 parts by mass, more preferably 5 parts by mass, and still more preferably 8 parts by mass, with respect to 100 parts by mass of the base polymer, from the viewpoint of securing sensitivity and developability as a resist. The upper limit of the content of the radiation-sensitive acid generator (I) is preferably 50 parts by mass, more preferably 40 parts by mass, and still more preferably 35 parts by mass, with respect to 100 parts by mass of the base polymer, from the viewpoint of securing transparency to radiation.

### (Acid Diffusion Controlling Agent)

If necessary, the radiation-sensitive composition may contain an acid diffusion controlling agent. As the acid diffusion controlling agent, the radiation-sensitive acid generating agent (II) can be suitably employed among the radiation-sensitive acid generating agents. The acid diffusion controlling agent has the effect of controlling a diffusion phenomenon of an acid generated from the radiation-sensitive acid generator by exposure in a resist film to prevent an undesired chemical reaction in an unexposed area. The storage stability of the resulting radiation-sensitive composition is improved. The resolution of a resist pattern is further improved, the line width change of a resist pattern due to variation in post exposure delay time between exposure and development treatment can be prevented, and a radiation-sensitive composition excellent in process stability can be obtained.

Examples of other acid diffusion controlling agents include a nitrogen-containing compound including one to three nitrogen atoms in the same molecule, an amide group-containing compound, a urea compound, and a nitrogen-containing heterocyclic compound. As these nitrogen-containing organic compounds, a compound containing an acid-dissociable group can also be used.

The lower limit of the content of the acid diffusion controlling agent is preferably 1 part by mass, more preferably 3 parts by mass, still more preferably 5 parts by mass based on 100 parts by mass of the base polymer. The upper limit of the content is preferably 40 parts by mass, more preferably 35 parts by mass, still more preferably 30 parts by mass.

When the content of the acid diffusion controlling agent is set within the above range, the lithographic performance of the radiation-sensitive composition can be further improved. The radiation-sensitive composition may include one type of the acid diffusion controlling agent, or two or more acid diffusion controlling agents in combination.

### (Solvent)

The radiation-sensitive composition according to the present embodiment contains a solvent. The solvent is not particularly limited as long as the solvent is a solvent capable of dissolving or dispersing the first polymer and the second polymer, and the radiation-sensitive acid generator and the like contained as desired.

Examples of the solvent include an alcohol-based solvent, an ether-based solvent, a ketone-based solvent, an amide-based solvent, an ester-based solvent, and a hydrocarbon-based solvent.

### Examples of the Alcohol-Based Solvent Include

a monoalcohol-based solvent having 1 to 18 carbon atoms, including iso-propanol, 4-methyl-2-pentanol, n-hexanol, 2-ethylhexanol, furfuryl alcohol, cyclohexanol, 3,3,5-trimethylcyclohexanol, and diacetone alcohol;
a polyhydric alcohol having 2 to 18 carbon atoms, including ethylene glycol, 1,2-propylene glycol, 2-methyl-2,4-pentanediol, 2,5-hexanediol, diethylene glycol, dipropylene glycol, triethylene glycol, and tripropylene glycol; and
a polyhydric alcohol partial ether-based solvents obtained by etherifying a part of hydroxy groups of the polyhydric alcohol-based solvents such as 3-methoxybutanol and 1-methoxy-2-propanol (propylene glycol monomethyl ether).

In the present embodiment, the alcohol-based solvents also include alcohol acid ester-based solvents such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate.

### Examples of the Ether-Based Solvent Include

a dialkyl ether-based solvent, including diethyl ether, dipropyl ether, dibutyl ether and diisoamyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

### Examples of the Ketone-Based Solvent Include

a chain ketone-based solvent, including acetone, butanone, and methyl-iso-butyl ketone;
a cyclic ketone-based solvent, including cyclopentanone, cyclohexanone, and methylcyclohexanone; and
2,4-pentanedione, acetonylacetone, and acetophenone.

### Examples of the Amide-Based Solvent Include

a cyclic amide-based solvent, including N,N′-dimethyl imidazolidinone and N-methylpyrrolidone; and
a chain amide-based solvent, including N-methylformamide, N,N-dimethylformamide, N,N-diethylformamide, acetamide, N-methylacetamide, N,N-dimethylacetamide, and N-methylpropionamide.

### Examples of the Ester-Based Solvent Include

a monocarboxylate ester-based solvent, including n-butyl acetate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including γ-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, and diethyl phthalate.

### Examples of the Hydrocarbon-Based Solvent Include

an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among these, an alcohol-based solvent and an ester-based solvent are preferable, a polyhydric alcohol partial ether-based solvent, a polyhydric alcohol partial ether acetate-based solvent, a lactone-based solvent, and an alcohol acid ester-based solvent are more preferable, and propylene glycol monomethyl ether, ethyl lactate, propylene glycol monomethyl ether acetate, and γ-butyrolactone are still more preferable. The radiation-sensitive composition may contain one solvent, or two or more solvents.

### (Other Optional Components)

The radiation-sensitive composition may contain other optional components other than the above-descried components. Examples of the other optional components include a crosslinking agent, a localization enhancing agent, a surfactant, an alicyclic skeleton-containing compound, and a sensitizer. In addition, it is preferable that these other optional components do not have a perfluoromethyl group (—CF₃) or a perfluoromethylene group (—CF₂—). These other optional components may be used singly, or two or more thereof may be used in combination. The content of the other optional components is usually 5 parts by mass or less based on 100 parts by mass of the base polymer.

### <Method for Preparing Radiation-Sensitive Composition>

The radiation-sensitive composition can be prepared by, for example, mixing the first polymer, the second polymer, and the solvent with the radiation-sensitive acid generator, the acid diffusion controlling agent, and the like as necessary at a predetermined ratio. The radiation-sensitive composition is preferably filtered through, for example, a filter having a pore size of about 0.5 μm after mixing. The solid matter concentration of the radiation-sensitive composition is usually 0.1 mass % to 50 mass %, preferably 0.5 mass % to 30 mass %, more preferably 1 mass % to 20 mass %.

### <Method for Forming Pattern>

A pattern forming method according to an embodiment of the present disclosure includes:
(1) applying the radiation-sensitive composition directly or indirectly to a substrate to form a resist film (hereinafter, also referred to as a “resist film forming step”);
(2) exposing the resist film (hereinafter, also referred to as an “exposure step”); and
(3) developing the exposed resist film (hereinafter, also referred to as a “developing step”).

The method for forming a pattern uses the above-described radiation-sensitive composition excellent in various resist performances, and therefore a high-quality resist pattern can be formed. Hereinbelow, each of the steps will be described.

### [Resist Film Forming Step]

In this step (the above mentioned step (1)), a resist film is formed with the radiation-sensitive composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60 °C to 150 °C, and preferably from 80 °C to 140 °C. The duration of PB is typically from 5 seconds to 600 seconds, and preferably from 10 seconds to 300 seconds. The thickness of the resist film formed is preferably 10 nm to 1,000 nm, and more preferably 10 nm to 500 nm.

When the immersion exposure is carried out, irrespective of presence of a water repellent polymer additive such as the second polymer in the radiation-sensitive composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

When the next step, the exposure step, is performed with KrF excimer laser light or radiation having a wavelength of 50 nm or less, it is preferable to use a polymer having the structural unit (I) and the structural unit (IV) as the base polymer in the composition.

### [Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and y ray; an electron beam; and a charged particle radiation such as a ray. Among them, visible ray, far ultraviolet ray, an electron beam, or EUV is preferred. g-line, i-line, ArF excimer laser light (wavelength is 193 nm), KrF excimer laser light (wavelength is 248 nm), an electron beam, or EUV is more preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the polymer by the acid generated from the radiation-sensitive acid generator with the exposure in the exposed part of the resist film. The difference of solubility into the developer between the exposed part and the non-exposed part is generated by the PEB. The temperature of PEB is typically from 50 °C to 180 °C, and preferably from 80 °C to 130 °C. The duration of PEB is typically from 5 seconds to 600 seconds, and preferably from 10 seconds to 300 seconds.

### [Developing Step]

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive composition. Among them, an ether-based solvent, an ester-based solvent or a ketone-based solvent is preferred. As the ether-based solvent, a glycol ether-based solvent is preferable, and ethylene glycol monomethyl ether and propylene glycol monomethyl ether are more preferable. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably 80% by mass or more, more preferably 90% by mass or more, further preferably 95% by mass or more, and particularly preferably 99% by mass or more. Examples of the ingredient other than the organic solvent in the developer include water and silicone oil.

As described above, the developer may be either an alkaline developer or an organic solvent developer, but it is preferable that the developer contain an alkaline aqueous solution and the resulting pattern is a positive pattern.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### Second Embodiment

<Composition for forming liquid immersion upper film>

The composition for forming a liquid immersion upper film according to the present embodiment includes:
a second polymer containing a structural unit (i) derived from a compound represented by the formula (F1); and
a solvent.

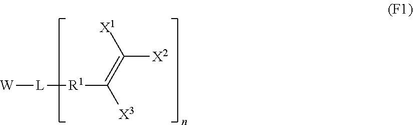

wherein, in the formula (F1),
W is a polymerizable group,
L is a single bond or an (n+1)-valent linking group,
R¹ is a divalent hydrocarbon group having 1 to 10 carbon atoms,
X¹, X², and X³ are each independently a hydrogen atom or a fluorine atom, at least one selected from the group consisting of X¹, X², and X³ is a fluorine atom,
n is an integer of 1 to 3, n is 1 when L is a single bond, and a plurality of R¹s, X¹s, X²s, or X³s are the same as or different from each other when n is 2 or more.

The compound is preferably represented by the formula (f1-1) or (f1-2).

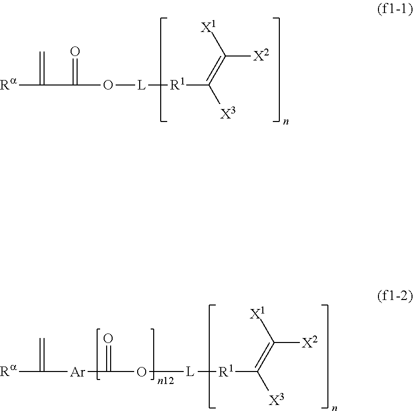

wherein, in the formulas (f1-1) and (f1-2),
R^{α} is a hydrogen atom, a halogen atom, or a monovalent organic group having 1 to 10 carbon atoms,
L, R¹, X¹, X², X³, and n have the same meaning as in the formula (F1), n is 1 when L¹¹ is a single bond, and
in the formula (f1-2),
Ar is a substituted or unsubstituted divalent aromatic ring, and
n₁₂ is 0 or 1.

As the polymer, the method for producing the same, and the solvent in the composition for forming a liquid immersion upper film, the second polymer, the method for producing the same, and the solvent in the radiation-sensitive composition according to the first embodiment can be suitably employed. The composition for forming a liquid immersion upper film may contain the other optional components in the above radiation-sensitive composition.

As the method for preparing the composition for forming a liquid immersion upper film, the method for preparing a radiation-sensitive composition according to the first embodiment can be suitably employed.

### <Method for Forming Pattern>

A method for forming a pattern according to the present embodiment includes:
applying a radiation-sensitive composition directly or indirectly to a substrate to form a resist film (hereinafter also referred to as “resist film forming step (a)”);
applying the composition for forming a liquid immersion upper film to the resist film to form a liquid immersion upper film (hereinafter also referred to as “liquid immersion upper film forming step (b)”);
subjecting the resist film provided with the liquid immersion upper film to immersion exposure (hereinafter also referred to as “immersion exposure step (c)”); and
developing the resist film subjected to the immersion exposure (hereinafter also referred to as “developing step (d)”).

As the resist film forming step (a), the immersion exposure step (c), and the developing step (d), the resist film forming step, the exposure step (limited to the case of immersion exposure), and the developing step in the method for forming a pattern according to the first embodiment can be suitably employed, respectively. As the radiation-sensitive composition in the resist film forming step (a), the radiation-sensitive composition according to the first embodiment (the second polymer may not be contained) can be suitably employed. Hereinafter, the liquid immersion upper film forming step (b) different from the corresponding step in the method for forming a pattern according to the first embodiment will be described.

[Liquid Immersion Upper Film Forming Step (b)]

In this step, the composition for forming a liquid immersion upper film is applied to the resist film to form a liquid immersion upper film. As the applying method, the applying method in the resist film forming step of the method for forming a pattern according to the first embodiment can be suitably employed. After the application, prebaking (PB) may be performed to volatilize the solvent in the coating film, as necessary. The PB temperature is usually 60 °C to 140 °C, preferably 80 °C to 120 °C. The PB duration is usually 5 seconds to 600 seconds, preferably 10 seconds to 300 seconds. The thickness of the liquid immersion upper film to be formed is preferably 10 nm to 500 nm, more preferably 10 nm to 200 nm.

### Third Embodiment

### <Compound>

The compound according to the present embodiment is a compound including a polymerizable group and a partial structure represented by the formula (a).

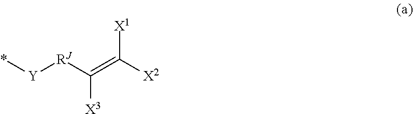

wherein, in the formula (a),
Y is a divalent heteroatom-containing group or a divalent linking group having three or more carbon atoms,
R^{J} is a divalent hydrocarbon group having one or two carbon atoms,
X¹, X², and X³ are each independently a hydrogen atom or a fluorine atom, at least one selected from the group consisting of X¹, X², and X³ is a fluorine atom, and
is a bond to an atom of a portion other than the partial structure in the compound.

As the polymerizable group of the compound, the polymerizable group represented by W of the formula (F1) can be suitably employed.

As the divalent heteroatom-containing group represented by Y, the divalent heteroatom-containing group listed as the substituent that can be included in the polymerizable group of W in the formula (F1) can be suitably employed.

As the divalent linking group having three or more carbon atoms represented by Y, a divalent group having three or more carbon atoms among the (n+1)-valent linking groups represented by L in the formula (F1) can be suitably employed.

Examples of the divalent hydrocarbon group having one or two carbon atoms represented by R^{J} include a methylene group, a methanediyl group, an ethenediyl group, and an ethynediyl group. Among them, a methylene group and a methanediyl group are preferable.

It is preferable that at least two selected from the group consisting of X¹, X², and X³ be fluorine atoms, and it is more preferable that all of X¹, X², and X³ be fluorine atoms.

The polymerizable group and the partial structure are preferably bonded via a divalent organic group having 1 to 20 carbon atoms. As the divalent organic group having 1 to 20 carbon atoms, a group obtained by removing 1 hydrogen atom from the monovalent organic group having 1 to 20 carbon atoms listed as the substituent that can be included in the polymerizable group of W in the formula (F1) can be suitably employed.

The compound including the partial structure represented by the formula (a) is preferably represented by the formula (A-1) or (A-2).

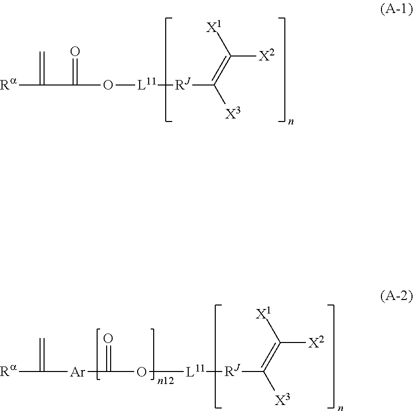

wherein, in the formulas (A-1) and (A-2),
R^{α} is a hydrogen atom, a halogen atom, or a monovalent organic group having 1 to 10 carbon atoms,
L¹¹ is a single bond, an (n+1)-valent linking group having one or more carbon atoms containing a heteroatom, or an (n+1)-valent linking group having three or more carbon atoms,
n is an integer of 1 to 3, n is 1 when L¹¹ is a single bond,
R^{J}, X¹, X², and X³ have the same meaning as in the formula (a), a plurality of RJs, X¹s, X²s, and X³s are the same as or different from each other when n is 2 or more, and
in the formula (A-2),
Ar is a substituted or unsubstituted divalent aromatic ring, and
n₁₂ is 0 or 1.

In the formulas (A-1) and (A-2), R^{a}, n, Ar, and n₁₂ have the same meaning as in the formula (f1-1) or (f1-2).

As the (n+1)-valent linking group having one or more carbon atoms and containing a heteroatom represented by L¹¹, the group (α) described as L in the formula (F1) can be suitably employed.

As the (n+1)-valent linking group having three or more carbon atoms represented by L¹¹, a group corresponding to three or more carbon atoms among the (n+1)-valent linking groups represented by L in the formula (F1) can be suitably employed.

Specific examples of the compound represented by the formula (A-1) or (A-2) include the formulas (f1-1) to (f1-9), (f1-11) to (f1-21), (f1-23) to (f1-33), and (f1-35) to (f1-38).

As a method for synthesizing the compound including the partial structure represented by the formula (a), the method for synthesizing the compound represented by the formula (F1) can be suitably employed.

### EXAMPLES

Hereinafter, the present invention will be specifically described with reference to Examples, but the present invention is not limited to these Examples. Methods for measuring various physical property values are shown below.

### [Weight-Average Molecular Weight (Mw) and Number-Average Molecular Weight (Mn)]

The Mw and the Mn of the first and second polymers were measured by gel permeation chromatography (GPC) using GPC columns of Tosoh Corporation (“G2000HXL”×2, “G3000HXL”×1, “G4000HXL”×1) under the following conditions. The degree of dispersion (Mw/Mn) was calculated from the measurement results of Mw and Mn.
Elution solvent: tetrahydrofuran
Flow rate: 1.0 mL/min
Sample concentration: 1.0 mass %
Sample injection amount: 100 μL
Column temperature: 40 °C
Detector: differential refractometer
Standard material: monodisperse polystyrene

### [¹³C-NMR Analysis]

¹³C-NMR analysis of the first and second polymers was performed using a nuclear magnetic resonance apparatus (“JNM-Delta400” manufactured by JEOL Ltd.).

### Synthesis of compound (monomer) [F]

A compound (monomer) [F] represented by the formula below was synthesized.

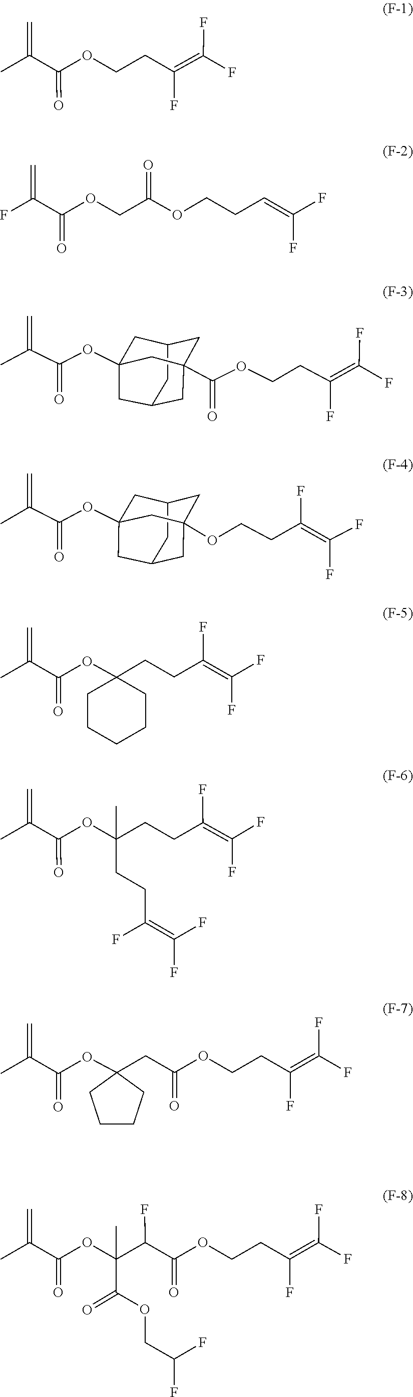

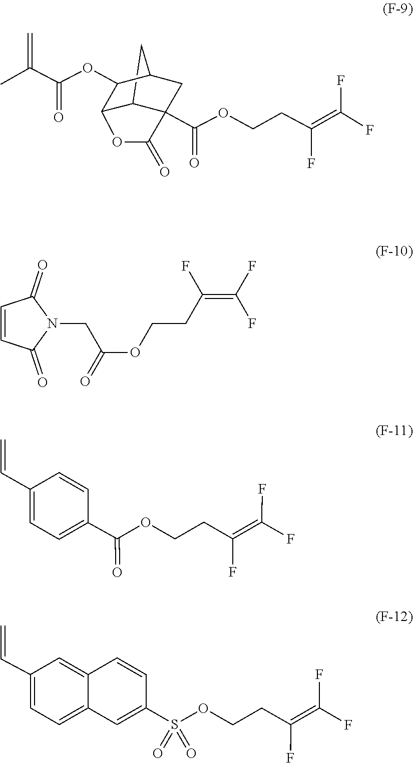 [SMILES: C=C(C)C(=O)OC1C2CC3C1OC(=O)C3(C(=O)OCCC(F)=C(F)F)C2 ; O=C(CN1C(=O)C=CC1=O)OCCC(F)=C(F)F ; C=Cc1ccc(C(=O)OCCC(F)=C(F)F)cc1 ; C=Cc1ccc2cc(S(=O)(=O)OCCC(F)=C(F)F)ccc2c1]

### Example A1

### (Synthesis of compound (F-1))

A compound (F-1) was synthesized according to the following synthesis scheme.

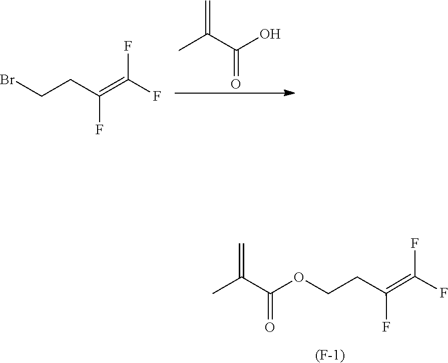

To a reaction vessel were added 20.0 mmol of 4-bromo-1,1,2-trifluoro-1-butene, 30.0 mmol of potassium carbonate, 30.0 mmol of methacrylic acid, and 50 g of acetone, and the mixture was stirred at 50 °C for 4 hours. Thereafter, the reaction solution was cooled to 30 °C or lower, diluted by adding water, and then extracted by adding ethyl acetate, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a compound (F-1) in a good yield.

### [Examples A2 to A4](synthesis of compounds (F-2) to (F-4))

Compounds represented by formulas (F-2) to (F-4) were synthesized in the same manner as in Example A1 except that the raw materials and the precursor were changed as appropriate (hereinafter the compounds represented by the formulas (F-2) to (F-4) are sometimes referred to as “compounds (F-2) to (F-4)” or “monomers (F-2) to (F-4)”).

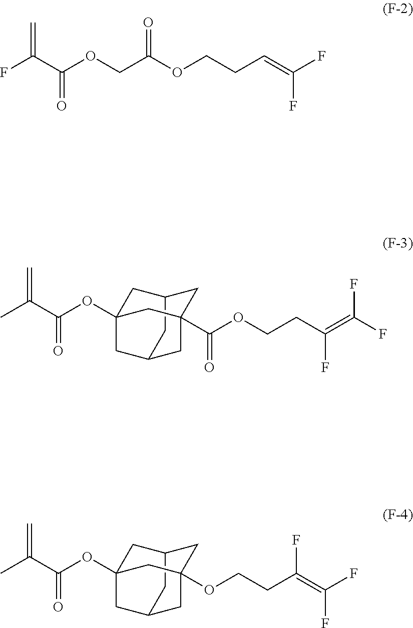 [SMILES: C=C(F)C(=O)OCC(=O)OCCC=C(F)F ; C=C(C)C(=O)OC12CC3CC(C1)CC(C(=O)OCCC(F)=C(F)F)(C3)C2 ; C=C(C)C(=O)OC12CC3CC(CC(OCCC(F)=C(F)F)(C3)C1)C2]

### [Example A5](Synthesis of Compound (F-5))

A compound (F-5) was synthesized according to the following synthesis scheme.

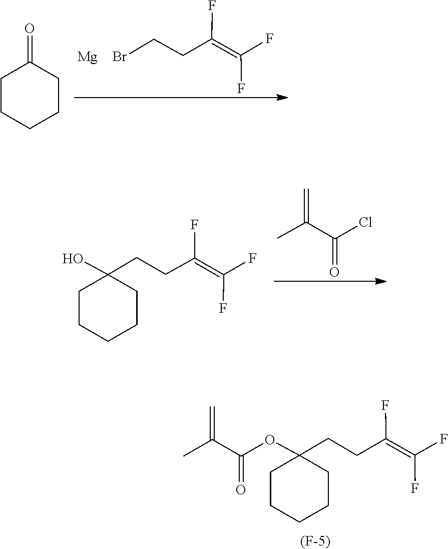

To a reaction vessel were added 20.0 mmol of 4-bromo-1,1,2-trifluoro-1-butene, 25.0 mmol of magnesium, and 50 g of tetrahydrofuran, and the mixture was stirred at room temperature for 1 hour. Thereafter, 20.0 mmol of cyclohexanone was added to the reaction solution, and the resulting mixture was further stirred at room temperature for 6 hours. Thereafter, a saturated aqueous solution of ammonium chloride was added to the reaction solution to stop the reaction, ethyl acetate was then added thereto to perform extraction, and the organic layer was separated. The resulting organic layer was washed with a saturated aqueous solution of sodium chloride and then with water. After the organic layer was dried over sodium sulfate, the solvent was distilled off, and the residue was purified by column chromatography, affording an alcohol form in a good yield.

To the alcohol form, 30.0 mmol of triethylamine, 30.0 mmol of methacrylic acid chloride, and 50 g of tetrahydrofuran were added, and the mixture was stirred at 80 °C for 1 hour. Thereafter, the reaction solution was cooled to 30 °C or lower, a saturated aqueous solution of ammonium chloride was added to stop the reaction, ethyl acetate was then added thereto to perform extraction, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a compound (F-5) in a good yield.

### [Example A6](Synthesis of Compound (F-6))

A compound represented by formula (F-6) was synthesized in the same manner as in Example A5 except that the raw materials and the precursor were changed as appropriate (hereinafter the compound represented by the formula (F-6) is sometimes referred to as “compound (F-6)” or “monomer (F-6)”).

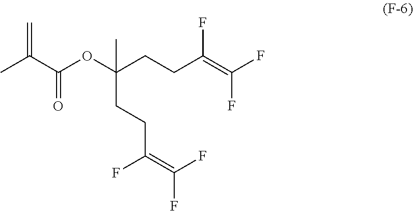 [SMILES: C=C(C)C(=O)OC(C)(CCC(F)=C(F)F)CCC(F)=C(F)F]

### [Example A7](Synthesis of Compound (F-7))

A compound (F-7) was synthesized according to the following synthesis scheme.

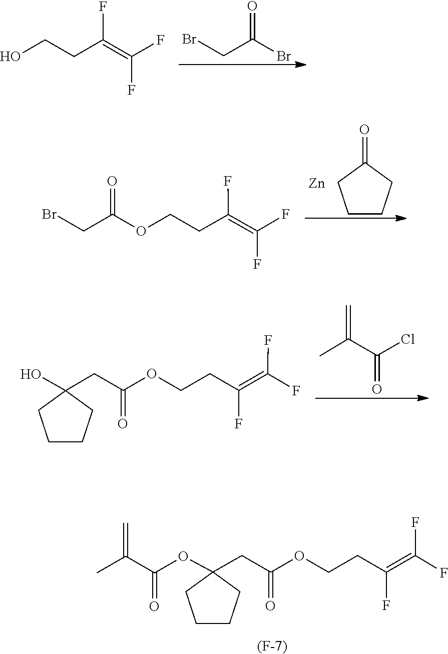

A reaction vessel was charged with 20.0 mmol of 4-hydroxy-1,1,2-trifluoro-1-butene, 30.0 mmol of triethylamine, 30.0 mmol of bromoacetyl bromide, and 50 g of tetrahydrofuran, and the mixture was stirred at 80 °C for 1 hour. Thereafter, the reaction solution was cooled to 30 °C or lower, a saturated aqueous solution of ammonium chloride was added to stop the reaction, ethyl acetate was then added thereto to perform extraction, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a bromo form in a good yield.

To the bromo form, 25.0 mmol of zinc powder, 2.00 mmol of chlorotrimethylsilane, and 50 g of tetrahydrofuran were added, and the mixture was stirred at room temperature for 1 hour. Thereafter, 20.0 mmol of cyclopentanone was added to the reaction solution, and the resulting mixture was further stirred at room temperature for 6 hours. Thereafter, a saturated aqueous solution of ammonium chloride was added to the reaction solution to stop the reaction, ethyl acetate was then added thereto to perform extraction, and the organic layer was separated. The resulting organic layer was washed with a saturated aqueous solution of sodium chloride and then with water. After the organic layer was dried over sodium sulfate, the solvent was distilled off, and the residue was purified by column chromatography, affording an alcohol form in a good yield.

To the alcohol form, 30.0 mmol of triethylamine, 30.0 mmol of methacrylic acid chloride, and 50 g of tetrahydrofuran were added, and the mixture was stirred at 80 °C for 1 hour. Thereafter, the reaction solution was cooled to 30 °C or lower, a saturated aqueous solution of ammonium chloride was added to stop the reaction, ethyl acetate was then added thereto to perform extraction, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a compound (F-7) in a good yield.

### [Example A8](Synthesis of Compound (F-8))

A compound represented by formula (F-8) was synthesized in the same manner as in Example A7 except that the raw materials and the precursor were changed as appropriate (hereinafter the compound represented by the formula (F-8) is sometimes referred to as “compound (F-8)” or “monomer (F-8)”)

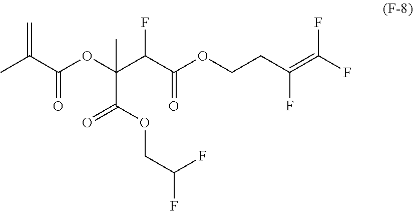 [SMILES: C=C(C)C(=O)OC(C)(C(=O)OCC(F)F)C(F)C(=O)OCCC(F)=C(F)F]

### [Example A9](Synthesis of Compound (F-9))

A compound (F-9) was synthesized according to the following synthesis scheme.

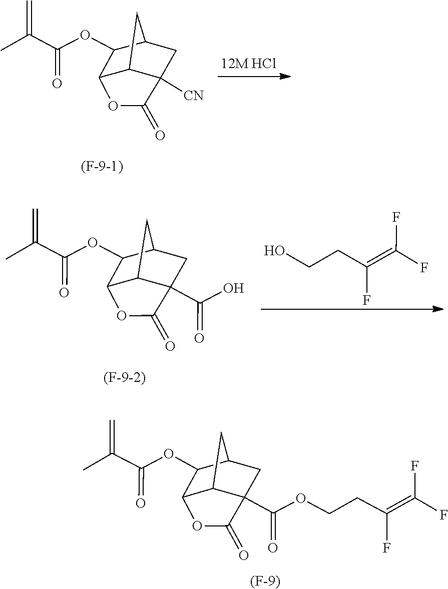

To a reaction vessel were added 20.0 mmol of the compound (F-9-1), 50 g of 12-M hydrochloric acid, and 10 g of tetrahydrofuran, and the mixture was stirred at 80 °C for 5 hours. Thereafter, the reaction solution was cooled to 30 °C or lower, diluted by adding water, and then extracted by adding ethyl acetate, and the organic layer was separated. The resulting organic layer was washed with a saturated aqueous solution of sodium chloride and then with water. After the organic layer was dried over sodium sulfate, the solvent was distilled off, affording a compound (F-9-2) in a good yield.

With the compound (F-9-2), 20.0 mmol of 1-(3-dimethylaminopropyl)-3-ethylcarbodiimide hydrochloride, 4.0 mmol of 4-dimethylaminopyridine, 20.0 mmol of 4-hydroxy-1,1,2-trifluoro-1-butene, and 50 g of dichloromethane were mixed, and the mixture was stirred at room temperature for 5 hours. Thereafter, the mixture was diluted by adding water, dichloromethane was then added to perform extraction, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a compound (F-9) in a good yield.

### [Example A10](Synthesis of Compound (F-10))

A compound (F-10) was synthesized according to the following synthesis scheme.

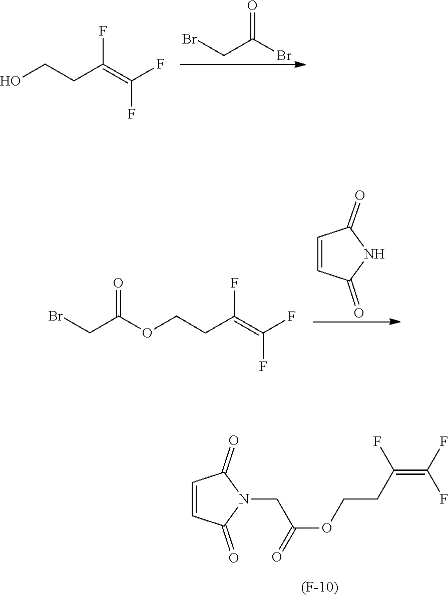

A reaction vessel was charged with 20.0 mmol of 4-hydroxy-1,1,2-trifluoro-1-butene, 30.0 mmol of triethylamine, 30.0 mmol of bromoacetyl bromide, and 50 g of tetrahydrofuran, and the mixture was stirred at 80 °C for 1 hour. Thereafter, the reaction solution was cooled to 30 °C or lower, a saturated aqueous solution of ammonium chloride was added to stop the reaction, ethyl acetate was then added thereto to perform extraction, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a bromo form in a good yield.

To the bromo form, 30.0 mmol of potassium carbonate, 30.0 mmol of maleimide, and 50 g of acetone were added, and the mixture was stirred at 50 °C for 4 hours. Thereafter, the reaction solution was cooled to 30 °C or lower, diluted by adding water, and then extracted by adding ethyl acetate, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a compound (F-10) in a good yield.

### [Example A11](Synthesis of Compound (F-11))

A compound (F-11) was synthesized according to the following synthesis scheme.

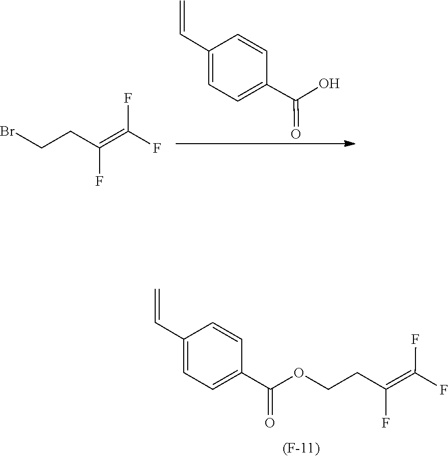

To a reaction vessel were added 20.0 mmol of 4-bromo-1,1,2-trifluoro-1-butene, 30.0 mmol of potassium carbonate, 30.0 mmol of 4-vinylbenzoic acid, and 50 g of acetone, and the mixture was stirred at 50 °C for 4 hours. Thereafter, the reaction solution was cooled to 30 °C or lower, diluted by adding water, and then extracted by adding ethyl acetate, and the organic layer was separated. The resulting organic layer was washed with a saturated aqueous solution of sodium chloride and then with water. After the organic layer was dried over sodium sulfate, the solvent was distilled off, and the residue was purified by column chromatography, affording a compound (F-11) in a good yield.

### [Example A12](Synthesis of Compound (F-12))

A compound represented by formula (F-12) was synthesized in the same manner as in Example All except that the raw materials and the precursor were changed as appropriate (hereinafter the compound represented by the formula (F-12) is sometimes referred to as “compound (F-12)” or “monomer (F-12)”).

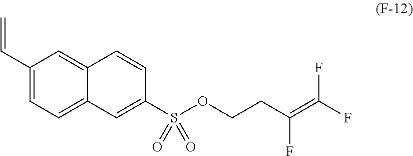 [SMILES: C=Cc1ccc2cc(S(=O)(=O)OCCC(F)=C(F)F)ccc2c1]

### Synthesis of First and Second Polymers

Among the monomers used in the synthesis of the first and second polymers, monomers other than the monomers (F-1) to (F-9) are described below. In the following synthesis examples, unless otherwise specified, a value represented by parts by mass is based on the total mass of the used monomers defined as 100 parts by mass, and a value represented by mol % is based on the total number of moles of the used monomers defined as 100 mol %.

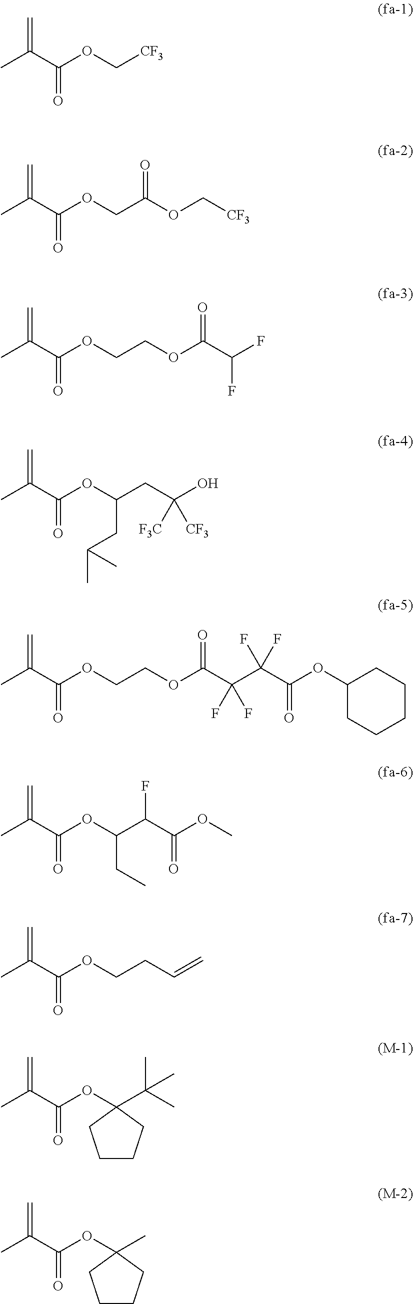

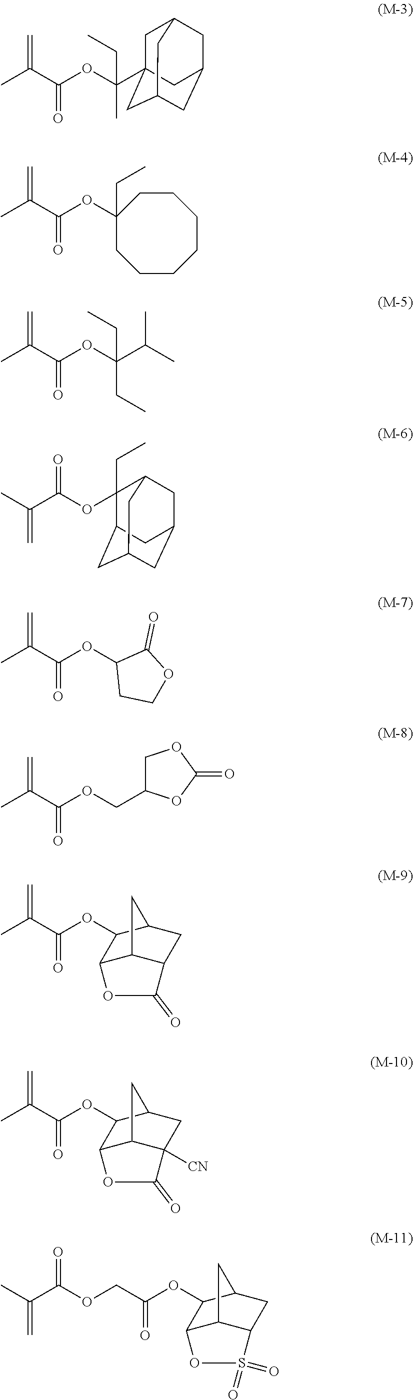

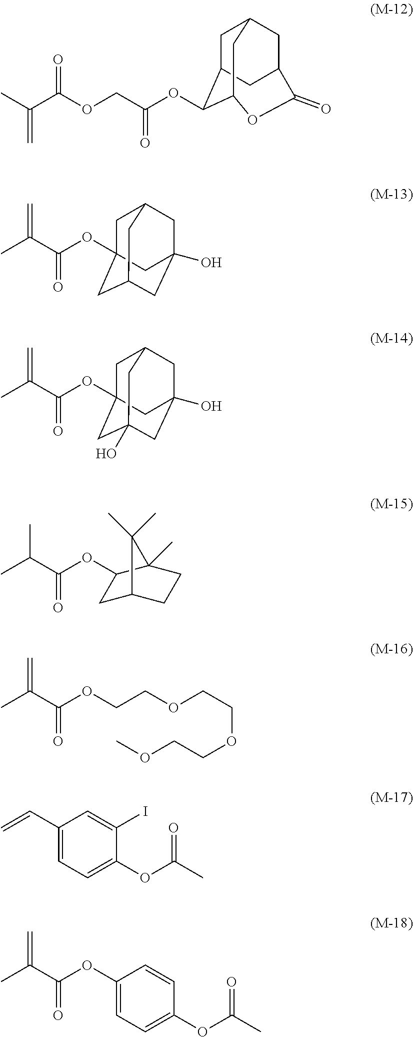

### Synthesis Example 1

### (Synthesis of First Polymer (A-1))

A monomer (M-1), a monomer (M-6), a monomer (M-7), a monomer (M-10), and a monomer (M-13) were dissolved at a molar ratio of 40/10/20/20/10 (mol %) in 2-butanone (200 parts by mass), and AIBN (azobisisobutyronitrile) (5 mol % based on 100 mol % in total of the monomers used) was added thereto as an initiator to prepare a monomer solution. Propylene glycol monomethyl ether acetate (100 parts by mass) was placed in a reaction vessel, and the reaction vessel was purged with nitrogen for 30 minutes. Then, the temperature inside the reaction vessel was adjusted to 80 °C, and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30 °C or lower. The polymerization solution cooled was poured into methanol (2,000 parts by mass), and a precipitated white powder was collected by filtration. The white powder separated by filtration was washed with methanol twice, then separated by filtration, and dried at 50 °C for 24 hours to obtain a white powdery first polymer (A-1) (yield: 78%). The first polymer (A-1) had an Mw of 6,000 and an Mw/Mn of 1.55. As a result of ¹³C-NMR analysis, the content ratios of the structural units derived from (M-1), (M-6), (M-7), (M-10), and (M-13) were 39.4 mol %, 9.8 mol %, 20.3 mol %, 20.4 mol %, and 10.1 mol %, respectively.

### Synthesis Examples 2 to 4

### (Synthesis of First Polymers (A-2) to (A-4))

First polymers (A-2) to (A-4) were synthesized in the same manner as in Synthesis Example 1 except that monomers of types and blending ratios shown in Table 1 below were used. The content by percent (mol %) of each of the structural units and physical property values (Mw and Mw/Mn) of the resulting first polymers are also shown in Table 1.

TABLE 1

| | | Monomer that gives | | | Monomer that gives | | | Monomer that gives | | | | |
|---|---|---|---|---|---|---|---|---|---|---|---|---|
| | | structural unit (I) | | | structural unit (II) | | | structural unit (III) | | | | |
| | | | | Content | | | Content | | | Content | | |
| | | | | ratio of | | | ratio of | | | ratio of | | |
| | [A] | | Blending | structural | | Blending | structural | | Blending | structural | | |
| | First | | ratio | unit | | ratio | unit | | ratio | unit | | |
| | polymer | Type | (mol %) | (mol %) | Type | (mol %) | (mol %) | Type | (mol %) | (mol %) | Mw | Mw/Mn |
| Synthesis | A-1 | M-1 | 40 | 39.4 | M-7 | 20 | 20.3 | M-13 | 10 | 10.1 | 6000 | 1.55 |
| Example 1 | | M-6 | 10 | 9.8 | M-10 | 20 | 20.4 | | | | | |
| Synthesis | A-2 | M-1 | 40 | 38.6 | M-8 | 20 | 21.0 | M-14 | 5 | 6.3 | 7500 | 1.58 |
| Example 2 | | M-3 | 10 | 8.9 | M-12 | 25 | 25.2 | | | | | |
| Synthesis | A-3 | M-2 | 50 | 50.1 | M-7 | 10 | 10.3 | M-13 | 10 | 10.5 | 12400 | 1.66 |
| Example 3 | | M-3 | 10 | 9.1 | M-11 | 20 | 20.0 | | | | | |
| Synthesis | A-4 | M-2 | 40 | 40.6 | M-7 | 25 | 25.4 | M-14 | 5 | 4.3 | 17300 | 1.65 |
| Example 4 | | | | | M-9 | 30 | 29.7 | | | | | |

### Synthesis Example 5

### (Synthesis of First Polymer (A-5))

Monomers (M-1), (M-13), and (M-17) were dissolved at a molar ratio of 40/10/50 (mol %) in 1-methoxy-2 propanol (200 parts by mass), and AIBN (5 mol %) was added thereto as an initiator to prepare a monomer solution. 1-methoxy-2-propanol (100 parts by mass) was placed in a reaction vessel, and the reaction vessel was purged with nitrogen for 30 minutes. Then, the temperature inside the reaction vessel was adjusted to 80 °C, and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30 °C or lower. The cooled polymerization solution was poured into hexane (2,000 parts by mass), and a precipitated white powder was collected by filtration. The white powder separated by filtration was washed with hexane twice, then separated by filtration, and dissolved in 1-methoxy-2-propanol (300 parts by mass). Next, methanol (500 parts by mass), triethylamine (50 parts by mass) and ultrapure water (10 parts by mass) were added, and a hydrolysis reaction was performed at 70 °C for 6 hours with stirring. After the completion of the reaction, the remaining solvent was distilled off. The resulting solid was dissolved in acetone (100 parts by mass), and the solution was added dropwise to water (500 parts by mass) to solidify a polymer. The resulting solid was separated by filtration, and dried at 50 °C for 13 hours to obtain a white powdery first polymer (A-5) (yield: 75%). The first polymer (A-5) had an Mw of 6,500 and an Mw/Mn of 1.61. As a result of ¹³C-NMR analysis, the content ratios of the structural units derived from (M-1), (M-13), and (M-17) were 39.5 mol %, 10.1 mol %, and 50.4 mol %, respectively.

### Synthesis Examples 6 and 7

### (Synthesis of First Polymers (A-6) and (A-7))

First polymers (A-6) and (A-7) were synthesized in the same manner as in Synthesis Example 5 except that monomers of types and blending ratios shown in Table 2 below were used. Table 2 also shows the content ratio (mol %) of each of the structural units and the physical property values (Mw and Mw/Mn) of the polymers obtained.

TABLE 2

| | | Monomer that gives | | | Monomer that gives | | | Monomer that gives | | | | |
|---|---|---|---|---|---|---|---|---|---|---|---|---|
| | | structural unit (I) | | | structural unit (III) | | | structural unit (IV) | | | | |
| | | | | Content | | | Content | | | Content | | |
| | | | | ratio of | | | ratio of | | | ratio of | | |
| | [A] | | Blending | structural | | Blending | structural | | Blending | structural | | |
| | First | | ratio | unit | | ratio | unit | | ratio | unit | | |
| | polymer | Type | (mol %) | (mol %) | Type | (mol %) | (mol %) | Type | (mol %) | (mol %) | Mw | Mw/Mn |
| Synthesis | A-5 | M-1 | 40 | 39.5 | M-13 | 10 | 10.1 | M-17 | 50 | 50.4 | 6500 | 1.61 |
| Example 5 | | | | | | | | | | | | |
| Synthesis | A-6 | M-2 | 40 | 38.1 | M-14 | 10 | 9.7 | M-18 | 50 | 52.2 | 10500 | 1.51 |
| Example 6 | | | | | | | | | | | | |
| Synthesis | A-7 | M-4 | 40 | 38.9 | M-14 | 10 | 9.5 | M-17 | 50 | 51.6 | 7800 | 1.54 |
| Example 7 | | | | | | | | | | | | |

### Synthesis Example 8

### (Synthesis of Second Polymer (E-1))

A monomer (F-3), a monomer (fa-6), and the monomer (M-1) were dissolved at a molar ratio of 60/10/30 (mol %) in 2-butanone (200 parts by mass), and MAIB (dimethyl 2,2′-azobis(isobutyrate)) (2 mol %) was added thereto as an initiator to prepare a monomer solution. 2-butanone (100 parts by mass) was placed in a reaction vessel, and the reaction vessel was purged with nitrogen for 30 minutes. Then, the temperature inside the reaction vessel was adjusted to 80 °C, and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30 °C or lower. The solvent was replaced with acetonitrile (400 parts by mass). Hexane (100 parts by mass) was then added, followed by stirring, and an acetonitrile layer was collected. The operation was repeated three times. By replacing the solvent with propylene glycol monomethyl ether acetate, a solution of a second polymer (E-1) was obtained (yield: 75%). The second polymer (E-1) had an Mw of 10,600 and an Mw/Mn of 1.54. As a result of ¹³C-NMR analysis, the content ratios of the structural units derived from (F-3), (fa-6), and (M-1) were 60.2 mol %, 9.2 mol %, and 30.6 mol %, respectively.

### [Synthesis Examples 9 to 38](Synthesis of Second Polymers (E-2) to (E-27) and (CE-1) to (CE-4))

Second polymers (E-2) to (E-27) and (CE-1) to (CE-4) were synthesized in the same manner as in Synthesis Example 8 except that the types, blending ratios of the monomers, and blending ratios of the polymerization initiator shown in Table 3 below were changed. The content ratio (mol %) and physical property values (Mw and Mw/Mn) of each of the structural units of the resulting second polymers are also shown in Table 3 below. In Table 3 below, “-” indicates that the corresponding component was not used (the same applies to the following tables).

TABLE 3

| | | | | | Monomer that gives | | | Monomer that gives | | | | |
|---|---|---|---|---|---|---|---|---|---|---|---|---|
| | | Monomer that gives | | | structural unit (ii) | | | structural unit (I) | | | | |
| | | structural unit (i) | | | and the like | | | and the like | | | | |
| | | | | Content | | | Content | | | Content | | |
| | | | | ratio of | | | ratio of | | | ratio of | | |
| | [E] | | Blending | structural | | Blending | structural | | Blending | structural | | |
| | Second | | ratio | unit | | ratio | unit | | ratio | unit | | |
| | polymer | Type | (mol %) | (mol %) | Type | (mol %) | (mol %) | Type | (mol %) | (mol %) | Mw | Mw/Mn |
| Synthesis | E-1 | F-3 | 60 | 60.2 | fa-6 | 10 | 9.2 | M-1 | 30 | 30.6 | 10600 | 1.54 |
| Example 8 | | | | | | | | | | | | |
| Synthesis | E-2 | F-1 | 60 | 60.4 | fa-6 | 10 | 8.8 | M-1 | 30 | 30.8 | 12100 | 1.55 |
| Example 9 | | | | | | | | | | | | |
| Synthesis | E-3 | F-2 | 60 | 59.6 | fa-6 | 10 | 8.4 | M-1 | 30 | 32.0 | 11600 | 1.51 |
| Example 10 | | | | | | | | | | | | |
| Synthesis | E-4 | F-4 | 60 | 58.4 | fa-6 | 10 | 8.9 | M-1 | 30 | 32.7 | 11200 | 1.52 |
| Example 11 | | | | | | | | | | | | |
| Synthesis | E-5 | F-5 | 60 | 59.0 | fa-6 | 10 | 9.4 | M-1 | 30 | 31.6 | 11300 | 1.49 |
| Example 12 | | | | | | | | | | | | |
| Synthesis | E-6 | F-6 | 60 | 60.1 | fa-6 | 10 | 8.9 | M-1 | 30 | 31.0 | 14200 | 1.59 |
| Example 13 | | | | | | | | | | | | |
| Synthesis | E-7 | F-7 | 60 | 60.0 | fa-6 | 10 | 9.6 | M-1 | 30 | 30.4 | 14400 | 1.46 |
| Example 14 | | | | | | | | | | | | |
| Synthesis | E-8 | F-8 | 60 | 59.8 | fa-6 | 10 | 9.0 | M-1 | 30 | 31.2 | 13200 | 1.59 |
| Example 15 | | | | | | | | | | | | |
| Synthesis | E-9 | F-9 | 60 | 61.1 | fa-6 | 10 | 8.3 | M-1 | 30 | 30.6 | 12100 | 1.54 |
| Example 16 | | | | | | | | | | | | |
| Synthesis | E-10 | F-10 | 60 | 58.7 | fa-6 | 10 | 8.7 | M-1 | 30 | 32.6 | 11000 | 1.58 |
| Example 17 | | | | | | | | | | | | |
| Synthesis | E-11 | F-11 | 60 | 59.4 | fa-6 | 10 | 9.4 | M-1 | 30 | 31.2 | 10900 | 1.54 |
| Example 18 | | | | | | | | | | | | |
| Synthesis | E-12 | F-12 | 60 | 59.8 | fa-6 | 10 | 9.3 | M-1 | 30 | 30.9 | 10500 | 1.52 |
| Example 19 | | | | | | | | | | | | |
| Synthesis | E-13 | F-3 | 60 | 60.5 | fa-2 | 10 | 10.4 | M-1 | 30 | 29.1 | 12200 | 1.44 |
| Example 20 | | | | | | | | | | | | |
| Synthesis | E-14 | F-3 | 60 | 60.8 | fa-3 | 10 | 10.7 | M-1 | 30 | 28.5 | 11700 | 1.54 |
| Example 21 | | | | | | | | | | | | |
| Synthesis | E-15 | F-3 | 60 | 61.0 | fa-4 | 10 | 9.7 | M-1 | 30 | 29.3 | 11800 | 1.54 |
| Example 22 | | | | | | | | | | | | |
| Synthesis | E-16 | F-3 | 60 | 60.4 | fa-5 | 10 | 10.0 | M-1 | 30 | 29.6 | 11600 | 1.54 |
| Example 23 | | | | | | | | | | | | |
| Synthesis | E-17 | F-3 | 60 | 59.0 | fa-6 | 10 | 9.3 | M-4 | 30 | 31.7 | 11500 | 1.53 |
| Example 24 | | | | | | | | | | | | |
| Synthesis | E-18 | F-3 | 60 | 60.1 | fa-6 | 10 | 8.9 | M-5 | 30 | 31.0 | 11600 | 1.55 |
| Example 25 | | | | | | | | | | | | |
| Synthesis | E-19 | F-3 | 60 | 60.0 | fa-6 | 10 | 9.0 | M-9 | 30 | 31.0 | 10900 | 1.54 |
| Example 26 | | | | | | | | | | | | |
| Synthesis | E-20 | F-3 | 60 | 59.8 | fa-6 | 10 | 10.0 | M-15 | 30 | 30.2 | 10500 | 1.52 |
| Example 27 | | | | | | | | | | | | |
| Synthesis | E-21 | F-3 | 60 | 61.1 | fa-6 | 10 | 9.8 | M-16 | 30 | 29.1 | 10400 | 1.51 |
| Example 28 | | | | | | | | | | | | |
| Synthesis | E-22 | F-3 | 40 | 40.2 | — | — | — | M-3 | 10 | 10.0 | 11100 | 1.50 |
| Example 29 | | F-6 | 40 | 38.4 | | | | M-10 | 10 | 11.4 | | |
| Synthesis | E-23 | F-8 | 50 | 51.2 | — | — | — | M-4 | 50 | 48.8 | 10700 | 1.54 |
| Example 30 | | | | | | | | | | | | |
| Synthesis | E-24 | F-5 | 25 | 24.9 | fa-3 | 25 | 24.6 | — | — | — | 7200 | 1.65 |
| Example 31 | | F-7 | 25 | 25.5 | fa-4 | 25 | 25.0 | | | | | |
| Synthesis | E-25 | F-3 | 35 | 36.0 | fa-5 | 10 | 10.2 | M-7 | 10 | 8.7 | 3600 | 1.76 |
| Example 32 | | F-11 | 35 | 34.5 | | | | M-13 | 10 | 10.6 | | |
| Synthesis | E-26 | F-5 | 10 | 11.8 | fa-4 | 10 | 8.9 | M-6 | 40 | 38.9 | 6100 | 1.65 |
| Example 33 | | F-12 | 10 | 10.5 | | | | M-15 | 30 | 29.9 | | |
| Synthesis | E-27 | F-3 | 100 | 100.0 | — | — | — | — | — | — | 10400 | 1.51 |
| Example 34 | | | | | | | | | | | | |
| Synthesis | CE-1 | — | — | — | fa-1 | 100 | 100.0 | — | — | — | 11000 | 1.67 |
| Example 35 | | | | | | | | | | | | |
| Synthesis | CE-2 | — | — | — | fa-1 | 70 | 70.3 | M-1 | 30 | 29.7 | 10200 | 1.59 |
| Example 36 | | | | | | | | | | | | |
| Synthesis | CE-3 | — | — | — | fa-2 | 70 | 69.6 | M-1 | 30 | 30.4 | 11300 | 1.72 |
| Example 37 | | | | | | | | | | | | |
| Synthesis | CE-4 | — | — | — | fa-7 | 70 | 71.1 | M-1 | 30 | 28.9 | 10800 | 1.63 |
| Example 38 | | | | | | | | | | | | |

### Preparation of Radiation-Sensitive Composition

Components other than the first polymer [A] and the second polymer [E] used in preparation of radiation-sensitive compositions are shown below.

### [Radiation-Sensitive Acid Generator [B]]

B-1 to B-12: Compounds represented by the formulas (B-1) to (B-12)

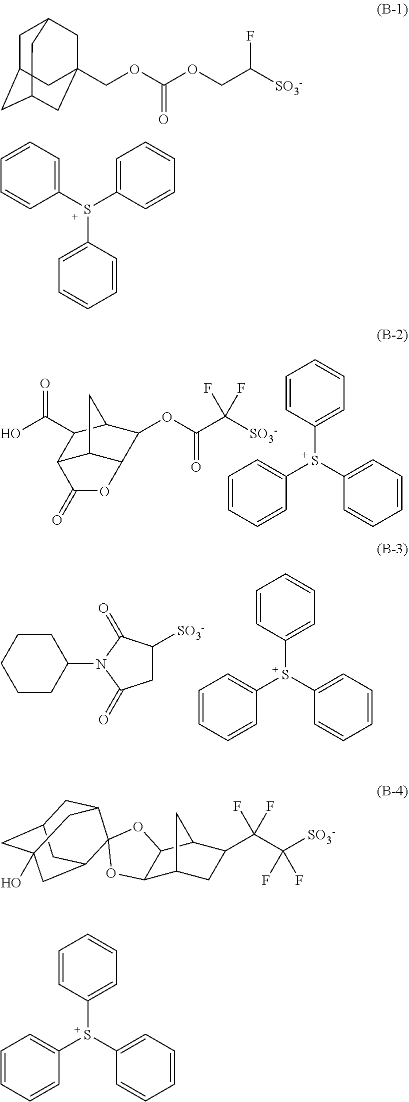

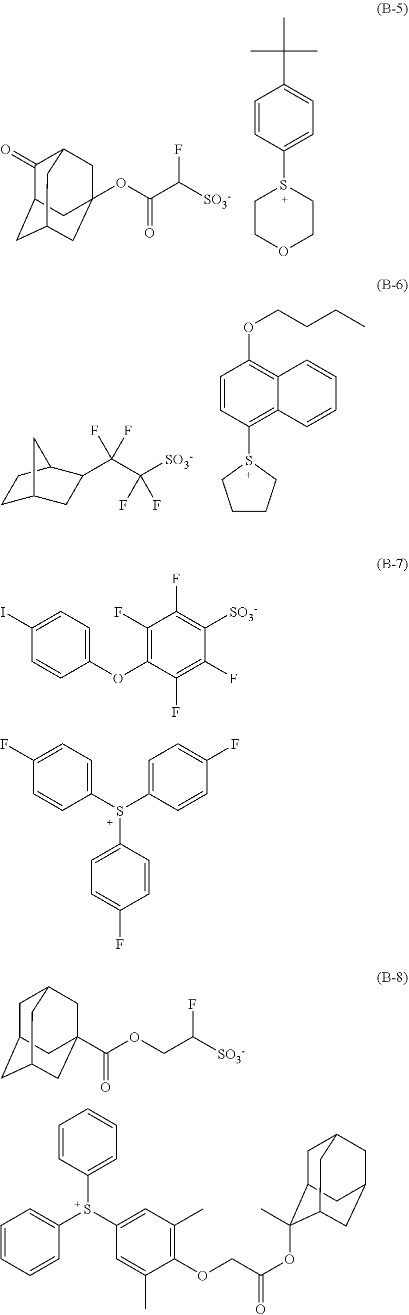

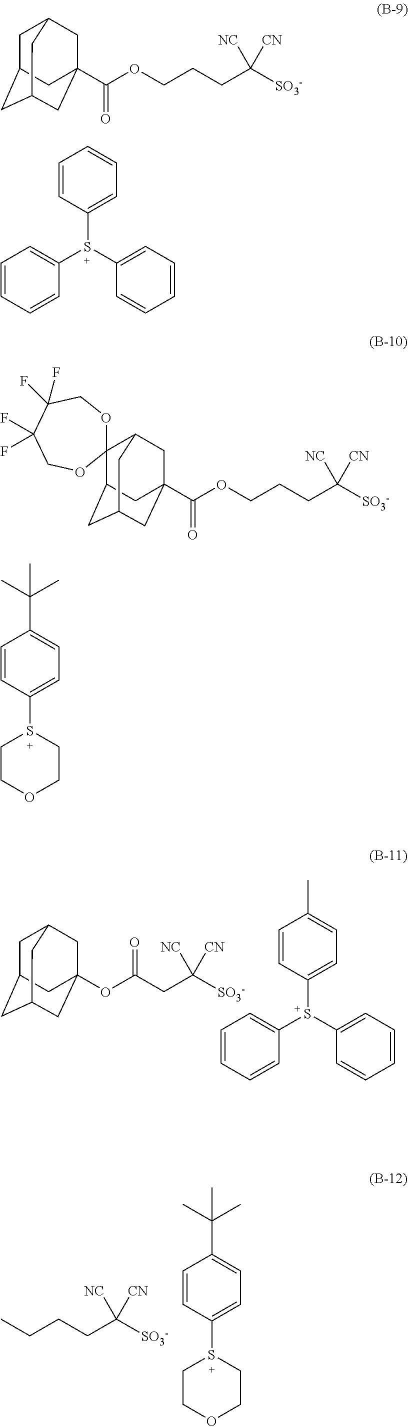

### [Acid Diffusion Controlling Agent [C]]

C-1 to C-6: Compounds represented by the formulas (C-1) to (C-6)

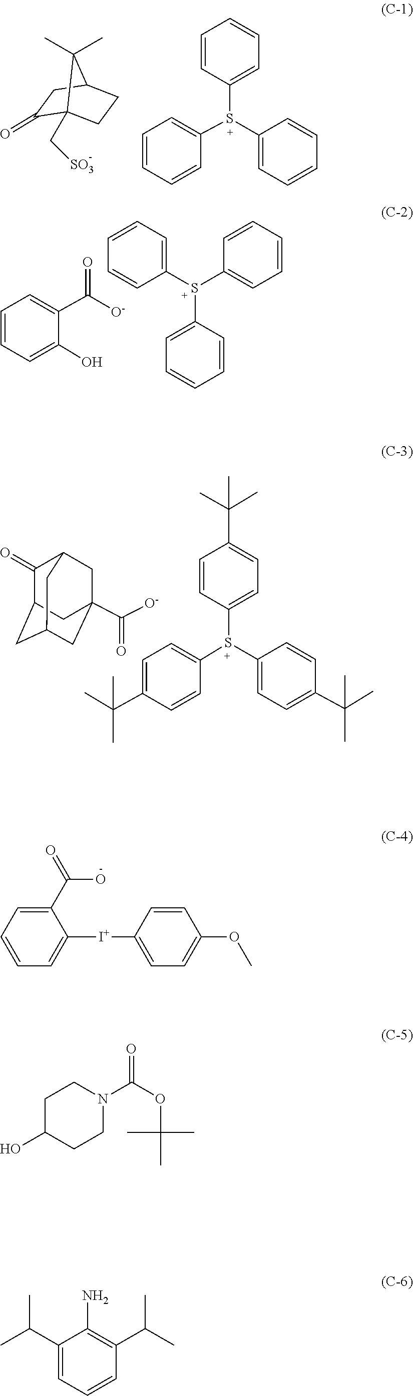

### [Solvent [D]]

D-1: Propylene glycol monomethyl ether acetate
D-2: Propylene glycol monomethyl ether
D-3: γ-Butyrolactone
D-4: Ethyl lactate

### [Other Additive Components [W]]

W-1: MEGAFACE EFS-321 (manufactured by DIC Corporation) (non-fluorine-based)
W-2: BYK-399 (manufactured by BYK Japan KK) (non-silicon-based)

### Preparation of Positive Radiation-Sensitive Composition for ArF Exposure

### Example 1

A radiation-sensitive composition (J-1) was prepared by mixing 100 parts by mass of (A-1) as the first polymer [A], 10.0 parts by mass of (B-1) as the radiation-sensitive acid generator [B], 8.0 parts by mass of (C-1) as the acid diffusion controlling agent [C], 5.0 parts by mass (solid content) of (E-1) as the second polymer [E], and 2,700 parts by mass of a mixed solvent of (D-1)/(D-2)/(D-3) as the solvent [D] and filtering the mixture through a membrane filter having a pore size of 0.2 μm.

### Examples 2 to 49 and Comparative Examples 1 to 4

Radiation-sensitive compositions (J-2) to (J-49) and (CJ-1) to (CJ-4) were prepared in the same manner as in Example 1 except that the components of the types and the contents shown in Tables 4-1 and 4-2 below were used.

TABLE 4-1

| | | First | | Radiation- | | Acid diffusion | | Second | | | | | |
|---|---|---|---|---|---|---|---|---|---|---|---|---|---|
| | | polymer | | sensitive acid | | controlling | | polymer | | Other additive | | Solvent | |
| | | [A] | | generator [B] | | agent [C] | | [E] | | components [W] | | [D] | |
| | Radiation- | | Content | | Content | | Content | | Content | | Content | | Content |
| | sensitive | | (Parts | | (Parts | | (Parts | | (Parts | | (Parts | | (Parts |
| | composition | Type | by mass) | Type | by mass) | Type | by mass) | Type | by mass) | Type | by mass) | Type | by mass) |
| Exam- | J-1 | A-1 | 100 | B-1 | 10.0 | C-1 | 8.0 | E-1 | 5.0 | — | — | D-1/D-2/ | 1000/1500/ |
| ple 1 | | | | | | | | | | | | D-3 | 200 |
| Exam- | J-2 | A-1 | 100 | B-1 | 10.0 | C-1 | 8.0 | E-2 | 5.0 | — | — | D-1/D-2/ | 1000/1500/ |
| ple 2 | | | | | | | | | | | | D-3 | 200 |
| Exam- | J-3 | A-1 | 100 | B-1 | 10.0 | C-1 | 8.0 | E-3 | 5.0 | — | — | D-1/D-2/ | 1000/1500/ |
| ple 3 | | | | | | | | | | | | D-3 | 200 |
| Exam- | J-4 | A-1 | 100 | B-1 | 10.0 | C-1 | 8.0 | E-4 | 5.0 | — | — | D-1/D-2/ | 1000/1500/ |
| ple 4 | | | | | | | | | | | | D-3 | 200 |
| Exam- | J-5 | A-1 | 100 | B-1 | 10.0 | C-1 | 8.0 | E-5 | 5.0 | — | — | D-1/D-2/ | 1000/1500/ |
| ple 5 | | | | | | | | | | | | D-3 | 200 |
| Exam- | J-6 | A-1 | 100 | B-1 | 10.0 | C-1 | 8.0 | E-6 | 5.0 | — | — | D-1/D-2/ | 1000/1500/ |
| ple 6 | | | | | | | | | | | | D-3 | 200 |
| Exam- | J-7 | A-1 | 100 | B-1 | 10.0 | C-1 | 8.0 | E-7 | 5.0 | — | — | D-1/D-2/ | 1000/1500/ |
| ple 7 | | | | | | | | | | | | D-3 | 200 |
| Exam- | J-8 | A-1 | 100 | B-1 | 10.0 | C-1 | 8.0 | E-8 | 5.0 | — | — | D-1/D-2/ | 1000/1500/ |
| ple 8 | | | | | | | | | | | | D-3 | 200 |
| Exam- | J-9 | A-1 | 100 | B-1 | 10.0 | C-1 | 8.0 | E-9 | 5.0 | — | — | D-1/D-2/ | 1000/1500/ |
| ple 9 | | | | | | | | | | | | D-3 | 200 |
| Exam- | J-10 | A-1 | 100 | B-1 | 10.0 | C-1 | 8.0 | E-10 | 5.0 | — | — | D-1/D-2/ | 1000/1500/ |
| ple 10 | | | | | | | | | | | | D-3 | 200 |
| Exam- | J-11 | A-1 | 100 | B-1 | 10.0 | C-1 | 8.0 | E-11 | 5.0 | — | — | D-1/D-2/ | 1000/1500/ |
| ple 11 | | | | | | | | | | | | D-3 | 200 |
| Exam- | J-12 | A-1 | 100 | B-1 | 10.0 | C-1 | 8.0 | E-12 | 5.0 | — | — | D-1/D-2/ | 1000/1500/ |
| ple 12 | | | | | | | | | | | | D-3 | 200 |
| Exam- | J-13 | A-1 | 100 | B-1 | 10.0 | C-1 | 8.0 | E-13 | 5.0 | — | — | D-1/D-2/ | 1000/1500/ |
| ple 13 | | | | | | | | | | | | D-3 | 200 |
| Exam- | J-14 | A-1 | 100 | B-1 | 10.0 | C-1 | 8.0 | E-14 | 5.0 | — | — | D-1/D-2/ | 1000/1500/ |
| ple 14 | | | | | | | | | | | | D-3 | 200 |
| Exam- | J-15 | A-1 | 100 | B-1 | 10.0 | C-1 | 8.0 | E-15 | 5.0 | — | — | D-1/D-2/ | 1000/1500/ |
| ple 15 | | | | | | | | | | | | D-3 | 200 |
| Exam- | J-16 | A-1 | 100 | B-1 | 10.0 | C-1 | 8.0 | E-16 | 5.0 | — | — | D-1/D-2/ | 1000/1500/ |
| ple 16 | | | | | | | | | | | | D-3 | 200 |
| Exam- | J-17 | A-1 | 100 | B-1 | 10.0 | C-1 | 8.0 | E-17 | 5.0 | — | — | D-1/D-2/ | 1000/1500/ |
| ple 17 | | | | | | | | | | | | D-3 | 200 |
| Exam- | J-18 | A-1 | 100 | B-1 | 10.0 | C-1 | 8.0 | E-18 | 5.0 | — | — | D-1/D-2/ | 1000/1500/ |
| ple 18 | | | | | | | | | | | | D-3 | 200 |
| Exam- | J-19 | A-1 | 100 | B-1 | 10.0 | C-1 | 8.0 | E-19 | 5.0 | — | — | D-1/D-2/ | 1000/1500/ |
| ple 19 | | | | | | | | | | | | D-3 | 200 |
| Exam- | J-20 | A-1 | 100 | B-1 | 10.0 | C-1 | 8.0 | E-20 | 5.0 | — | — | D-1/D-2/ | 1000/1500/ |
| ple 20 | | | | | | | | | | | | D-3 | 200 |
| Exam- | J-21 | A-1 | 100 | B-1 | 10.0 | C-1 | 8.0 | E-21 | 5.0 | — | — | D-1/D-2/ | 1000/1500/ |
| ple 21 | | | | | | | | | | | | D-3 | 200 |
| Exam- | J-22 | A-1 | 100 | B-1 | 10.0 | C-1 | 8.0 | E-22 | 5.0 | — | — | D-1/D-2/ | 1000/1500/ |
| ple 22 | | | | | | | | | | | | D-3 | 200 |
| Exam- | J-23 | A-1 | 100 | B-1 | 10.0 | C-1 | 8.0 | E-23 | 5.0 | — | — | D-1/D-2/ | 1000/1500/ |
| ple 23 | | | | | | | | | | | | D-3 | 200 |
| Exam- | J-24 | A-1 | 100 | B-1 | 10.0 | C-1 | 8.0 | E-24 | 5.0 | — | — | D-1/D-2/ | 1000/1500/ |
| ple 24 | | | | | | | | | | | | D-3 | 200 |
| Exam- | J-25 | A-1 | 100 | B-1 | 10.0 | C-1 | 8.0 | E-25 | 5.0 | — | — | D-1/D-2/ | 1000/1500/ |
| ple 25 | | | | | | | | | | | | D-3 | 200 |
| Exam- | J-26 | A-1 | 100 | B-1 | 10.0 | C-1 | 8.0 | E-26 | 5.0 | — | — | D-1/D-2/ | 1000/1500/ |
| ple 26 | | | | | | | | | | | | D-3 | 200 |
| Exam- | J-27 | A-1 | 100 | B-1 | 10.0 | C-1 | 8.0 | E-27 | 5.0 | — | — | D-1/D-2/ | 1000/1500/ |
| ple 27 | | | | | | | | | | | | D-3 | 200 |
| Exam- | J-31 | A-2 | 100 | B-1 | 10.0 | C-1 | 8.0 | E-1 | 5.0 | — | — | D-1/D-2/ | 1000/1500/ |
| ple 28 | | | | | | | | | | | | D-3 | 200 |
| Exam- | J-32 | A-3 | 100 | B-1 | 10.0 | C-1 | 8.0 | E-1 | 5.0 | — | — | D-1/D-2/ | 1000/1500/ |
| ple 29 | | | | | | | | | | | | D-3 | 200 |
| Exam- | J-33 | A-4 | 100 | B-1 | 10.0 | C-1 | 8.0 | E-1 | 5.0 | — | — | D-1/D-2/ | 1000/1500/ |
| ple 30 | | | | | | | | | | | | D-3 | 200 |

TABLE 4-2

| | | First | | Radiation- | | Acid diffusion | | Second | | | | | |
|---|---|---|---|---|---|---|---|---|---|---|---|---|---|
| | | polymer | | sensitive acid | | controlling | | polymer | | Other additive | | Solvent | |
| | | [A] | | generator [B] | | agent [C] | | [E] | | components [W] | | [D] | |
| | Radiation- | | Content | | Content | | Content | | Content | | Content | | Content |
| | sensitive | | (Parts | | (Parts | | (Parts | | (Parts | | (Parts | | (Parts |
| | composition | Type | by mass) | Type | by mass) | Type | by mass) | Type | by mass) | Type | by mass) | Type | by mass) |
| Exam- | J-34 | A-1 | 100 | B-2 | 10.0 | C-1 | 8.0 | E-1 | 5.0 | — | — | D-1/D-2/ | 1000/1500/ |
| ple 31 | | | | | | | | | | | | D-3 | 200 |
| Exam- | J-35 | A-1 | 100 | B-3 | 10.0 | C-1 | 8.0 | E-1 | 5.0 | — | — | D-1/D-2/ | 1000/1500/ |
| ple 32 | | | | | | | | | | | | D-3 | 200 |
| Exam- | J-36 | A-1 | 100 | B-4 | 10.0 | C-1 | 8.0 | E-1 | 5.0 | — | — | D-1/D-2/ | 1000/1500/ |
| ple 33 | | | | | | | | | | | | D-3 | 200 |
| Exam- | J-37 | A-1 | 100 | B-5 | 10.0 | C-1 | 8.0 | E-1 | 5.0 | — | — | D-1/D-2/ | 1000/1500/ |
| ple 34 | | | | | | | | | | | | D-3 | 200 |
| Exam- | J-38 | A-1 | 100 | B-6 | 10.0 | C-1 | 8.0 | E-1 | 5.0 | — | — | D-1/D-2/ | 1000/1500/ |
| ple 35 | | | | | | | | | | | | D-3 | 200 |
| Exam- | J-39 | A-1 | 100 | B-7 | 10.0 | C-1 | 8.0 | E-1 | 5.0 | — | — | D-1/D-2/ | 1000/1500/ |
| ple 36 | | | | | | | | | | | | D-3 | 200 |
| Exam- | J-40 | A-1 | 100 | B-8 | 10.0 | C-1 | 8.0 | E-1 | 5.0 | — | — | D-1/D-2/ | 1000/1500/ |
| ple 37 | | | | | | | | | | | | D-3 | 200 |
| Exam- | J-101 | A-1 | 100 | B-9 | 10.0 | C-1 | 8.0 | E-1 | 5.0 | — | — | D-1/D-2/ | 1000/1500/ |
| ple 101 | | | | | | | | | | | | D-3 | 200 |
| Exam- | J-102 | A-1 | 100 | B-10 | 10.0 | C-1 | 8.0 | E-1 | 5.0 | — | — | D-1/D-2/ | 1000/1500/ |
| ple 102 | | | | | | | | | | | | D-3 | 200 |
| Exam- | J-103 | A-1 | 100 | B-11 | 10.0 | C-1 | 8.0 | E-1 | 5.0 | — | — | D-1/D-2/ | 1000/1500/ |
| ple 103 | | | | | | | | | | | | D-3 | 200 |
| Exam- | J-104 | A-1 | 100 | B-12 | 10.0 | C-1 | 8.0 | E-1 | 5.0 | — | — | D-1/D-2/ | 1000/1500/ |
| ple 104 | | | | | | | | | | | | D-3 | 200 |
| Exam- | J-41 | A-1 | 100 | B-1 | 10.0 | C-2 | 8.0 | E-1 | 5.0 | — | — | D-1/D-2/ | 1000/1500/ |
| ple 38 | | | | | | | | | | | | D-3 | 200 |
| Exam- | J-42 | A-1 | 100 | B-1 | 10.0 | C-3 | 8.0 | E-1 | 5.0 | — | — | D-1/D-2/ | 1000/1500/ |
| ple 39 | | | | | | | | | | | | D-3 | 200 |
| Exam- | J-43 | A-1 | 100 | B-1 | 10.0 | C-4 | 8.0 | E-1 | 5.0 | — | — | D-1/D-2/ | 1000/1500/ |
| ple 40 | | | | | | | | | | | | D-3 | 200 |
| Exam- | J-44 | A-1 | 100 | B-1 | 10.0 | C-5 | 8.0 | E-1 | 5.0 | — | — | D-1/D-2/ | 1000/1500/ |
| ple 41 | | | | | | | | | | | | D-3 | 200 |
| Exam- | J-45 | A-1 | 100 | B-1 | 10.0 | C-6 | 8.0 | E-1 | 5.0 | — | — | D-1/D-2/ | 1000/1500/ |
| ple 42 | | | | | | | | | | | | D-3 | 200 |
| Exam- | J-46 | A-1 | 100 | B-1 | 10.0 | C-1 | 8.0 | E-1 | 2.5 | — | — | D-1/D-2/ | 1000/1500/ |
| ple 43 | | | | | | | | | | | | D-3 | 200 |
| Exam- | J-47 | A-1 | 100 | B-1 | 10.0 | C-1 | 8.0 | E-1 | 10.0 | — | — | D-1/D-2/ | 1000/1500/ |
| ple 44 | | | | | | | | | | | | D-3 | 200 |
| Exam- | J-48 | A-1 | 100 | B-1 | 10.0 | C-1 | 8.0 | E-1 | 15.0 | — | — | D-1/D-2/ | 1000/1500/ |
| ple 45 | | | | | | | | | | | | D-3 | 200 |
| Exam- | J-49 | A-1 | 100 | B-2/ | 5.0/5.0 | C-1 | 8.0 | E-1 | 5.0 | — | — | D-1/D-2/ | 1000/1500/ |
| ple 46 | | | | B-3 | | | | | | | | D-3 | 200 |
| Exam- | J-50 | A-1 | 100 | B-5/ | 5.0/5.0 | C-1 | 8.0 | E-1 | 5.0 | — | — | D-1/D-2/ | 1000/1500/ |
| ple 47 | | | | B-8 | | | | | | | | D-3 | 200 |
| Exam- | J-104 | A-1 | 100 | B-10/ | 3.0/7.0 | C-1 | 8.0 | E-1 | 5.0 | — | — | D-1/D-2/ | 1000/1500/ |
| ple 104 | | | | B-11 | | | | | | | | D-3 | 200 |
| Exam- | J-51 | A-1 | 100 | B-1 | 10.0 | C-1 | 8.0 | E-1 | 5.0 | W-1 | 1.0 | D-1/D-2/ | 1000/1500/ |
| ple 48 | | | | | | | | | | | | D-3 | 200 |
| Exam- | J-52 | A-1 | 100 | B-1 | 10.0 | C-1 | 8.0 | E-1 | 5.0 | W-2 | 1.0 | D-1/D-2/ | 1000/1500/ |
| ple 49 | | | | | | | | | | | | D-3 | 200 |
| Compar- | CJ-1 | A-1 | 100 | B-1 | 10.0 | C-1 | 8.0 | CE-1 | 5.0 | — | — | D-1/D-2/ | 1000/1500/ |
| ative | | | | | | | | | | | | D-3 | 200 |
| Exam- | | | | | | | | | | | | | |
| ple 1 | | | | | | | | | | | | | |
| Compar- | CJ-2 | A-1 | 100 | B-1 | 10.0 | C-1 | 8.0 | CE-2 | 5.0 | — | — | D-1/D-2/ | 1000/1500/ |
| ative | | | | | | | | | | | | D-3 | 200 |
| Exam- | | | | | | | | | | | | | |
| ple 2 | | | | | | | | | | | | | |
| Compar- | CJ-3 | A-1 | 100 | B-1 | 10.0 | C-1 | 8.0 | CE-3 | 5.0 | — | — | D-1/D-2/ | 1000/1500/ |
| ative | | | | | | | | | | | | D-3 | 200 |
| Exam- | | | | | | | | | | | | | |
| ple 3 | | | | | | | | | | | | | |
| Compar- | CJ-4 | A-1 | 100 | B-1 | 10.0 | C-1 | 8.0 | CE-4 | 5.0 | — | — | D-1/D-2/ | 1000/1500/ |
| ative | | | | | | | | | | | | D-3 | 200 |
| Exam- | | | | | | | | | | | | | |
| ple 4 | | | | | | | | | | | | | |

### <Formation of Resist Pattern Using Positive Radiation-Sensitive Composition for ArF Exposure>

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205 °C for 60 seconds to form an underlayer antireflection film having an average thickness of 100 nm. The positive radiation-sensitive composition for ArF immersion exposure prepared above was applied onto the underlayer antireflection film with use of the spin coater, followed by performing PB (pre-baking) at 100 °C for 60 seconds. Thereafter, cooling was performed at 23 °C for 30 seconds to form a resist film having an average thickness of 90 nm. Next, this resist film was exposed through a mask pattern of contact holes with a 42 nm hole and a 00 nm pitch using an ArF excimer laser immersion exposure apparatus (“TWINSCAN XT-1900i” manufactured by ASML) at NA=1.35 under an optical condition of Dipole (σ=0.8/0.6). After the exposure, PEB (post exposure baking) was performed at 100 °C for 60 seconds. Thereafter, the resist film was developed with an alkali with the use of a 2.38-mass % aqueous TMAH solution as an alkaline developer, followed by washing with water and further drying to form a positive resist pattern (pattern of contact holes with a 42 nm hole and a 90 nm pitch).

### <Evaluation>

The resist patterns formed using the positive radiation-sensitive compositions for ArF exposure were evaluated on the sensitivity, CDU, and number of defects after development according to the following methods. The receding contact angle of the resist films before ArF exposure was evaluated according to the following method. The results are shown in Tables 5-1 and 5-2 below. Note that a scanning electron microscope (“CG-5000” manufactured by Hitachi High-Technologies Corporation) was used for measurement of the length of the resist pattern.

### [Sensitivity]

An exposure dose at which contact holes with an 42 nm hole and a 90 nm pitch were formed in the resist pattern formation using the positive radiation-sensitive compositions for ArF exposure was defined as an optimum exposure dose, and this optimum exposure dose was defined as sensitivity (mJ/cm²). In the case of being 30 mJ/cm² or less, the sensitivity was evaluated as “good”, and in the case of being more than 30 mJ/cm², the sensitivity was evaluated as “poor”.

### [CDU]

Contact holes with a 42 nm hole and a 90 nm pitch were formed by irradiation with an optimum exposure dose determined in the evaluation of sensitivity. The formed resist pattern was observed from above the pattern with the use of the scanning electron microscope. The variation in diameter of the contact holes was measured at 500 points in total. The 3 sigma value was determined from the distribution of the measurement values, and defined as CDU (nm). The smaller the value of the CDU is, the smaller the roughness of the contact holes is, which is better. When the value was less than 3.0 nm, the CDU was evaluated to be “good”, and when the value was 3.0 nm or more, the CDU was evaluated to be “poor”.

[Receding Contact Angle after Prebaking (PB)]

The receding contact angle of the resist films before ArF exposure in the method for forming a resist pattern was measured by the following procedure in the environment at a room temperature of 23 °C, a relative humidity of 40%, and normal pressure, using DSA-10 of KRUSS Optronic GmbH.

A 25-μL water drop was formed on the resist film by discharging water through a needle of DSA-10, and then suctioned by the needle at a rate of 10 μL/min for 90 seconds, and the contact angle was measured every second (90 times in total). The average value of a total of 20 contact angles measured from the stabilization of the contact angle in the measurement was calculated and defined as the receding contact angle (°) after PB. When being 70° or more, the receding contact angle after PB was evaluated as “good”, and when less than 70°, evaluated as “poor”.

### [Number of Development Defects]

The resist film was exposed at the optimum exposure dose to form 42-nm contact holes at 90 nm pitches, thereby obtaining a wafer for defect inspection. The number of defects on this wafer for defect inspection was measured with the use of a defect inspection device (“KLA 2810” of KLA-Tencor Corporation). The defects having a diameter of 50 μm or less were determined to be derived from the resist film, and the number of the defects was calculated. The number of defects after development was determined as “extremely good” when the number of defects determined to be derived from the resist film was 10 or less, “good” when the number was 11 to 50, “acceptable” when the number was 51 to 100, and “poor” when the number exceeded 100.

TABLE 5-1

| | | Sensi- | | Receding | Number of |
|---|---|---|---|---|---|
| | Radiation- | tivity | | contact angle | development |
| | sensitive | (mJ/ | CDU | after PB | defects |
| | composition | cm²) | (nm) | (°) | (defects) |
| Example 1 | J-1 | 27 | 2.6 | 75 | 15 |
| Example 2 | J-2 | 24 | 2.7 | 78 | 29 |
| Example 3 | J-3 | 24 | 2.3 | 78 | 37 |
| Example 4 | J-4 | 25 | 2.1 | 77 | 25 |
| Example 5 | J-5 | 28 | 2.8 | 72 | 44 |
| Example 6 | J-6 | 25 | 2.7 | 77 | 36 |
| Example 7 | J-7 | 27 | 2.2 | 75 | 15 |
| Example 8 | J-8 | 24 | 2.3 | 77 | 12 |
| Example 9 | J-9 | 27 | 2.0 | 74 | 11 |
| Example 10 | J-10 | 27 | 2.3 | 73 | 41 |
| Example 11 | J-11 | 26 | 2.6 | 76 | 47 |
| Example 12 | J-12 | 24 | 2.2 | 73 | 20 |
| Example 13 | J-13 | 25 | 2.4 | 73 | 89 |
| Example 14 | J-14 | 27 | 2.7 | 72 | 47 |
| Example 15 | J-15 | 25 | 2.5 | 72 | 78 |
| Example 16 | J-16 | 25 | 2.4 | 75 | 80 |
| Example 17 | J-17 | 28 | 2.8 | 72 | 47 |
| Example 18 | J-18 | 26 | 2.2 | 77 | 45 |
| Example 19 | J-19 | 27 | 2.5 | 75 | 81 |
| Example 20 | J-20 | 26 | 2.6 | 77 | 14 |
| Example 21 | J-21 | 28 | 2.2 | 76 | 83 |
| Example 22 | J-22 | 24 | 2.4 | 78 | 77 |
| Example 23 | J-23 | 27 | 2.2 | 77 | 19 |
| Example 24 | J-24 | 28 | 2.4 | 75 | 73 |
| Example 25 | J-25 | 26 | 2.2 | 78 | 79 |
| Example 26 | J-26 | 26 | 2.4 | 76 | 88 |
| Example 27 | J-27 | 25 | 2.3 | 78 | 87 |
| Example 28 | J-31 | 24 | 2.4 | 77 | 30 |
| Example 29 | J-32 | 24 | 2.6 | 72 | 18 |
| Example 30 | J-33 | 24 | 2.6 | 74 | 20 |

TABLE 5-2

| | | Sensi- | | Receding | Number of |
|---|---|---|---|---|---|
| | Radiation- | tivity | | contact angle | development |
| | sensitive | (mJ/ | CDU | after PB | defects |
| | composition | cm²) | (nm) | (°) | (defects) |
| Example 31 | J-34 | 28 | 2.3 | 72 | 33 |
| Example 32 | J-35 | 24 | 2.2 | 75 | 46 |
| Example 33 | J-36 | 27 | 2.1 | 75 | 19 |
| Example 34 | J-37 | 27 | 2.4 | 76 | 37 |
| Example 35 | J-38 | 24 | 2.8 | 76 | 39 |
| Example 36 | J-39 | 26 | 2.7 | 78 | 34 |
| Example 37 | J-40 | 25 | 2.7 | 76 | 16 |
| Example 101 | J-101 | 22 | 1.9 | 76 | 3 |
| Example 102 | J-102 | 23 | 1.8 | 75 | 7 |
| Example 103 | J-103 | 21 | 1.9 | 77 | 2 |
| Example 104 | J-104 | 22 | 1.9 | 75 | 8 |
| Example 38 | J-41 | 24 | 2.4 | 76 | 30 |
| Example 39 | J-42 | 25 | 2.7 | 74 | 30 |
| Example 40 | J-43 | 28 | 2.1 | 75 | 20 |
| Example 41 | J-44 | 24 | 2.3 | 75 | 11 |
| Example 42 | J-45 | 27 | 2.7 | 75 | 17 |
| Example 43 | J-46 | 25 | 2.5 | 77 | 36 |
| Example 44 | J-47 | 24 | 2.3 | 73 | 44 |
| Example 45 | J-48 | 25 | 2.3 | 75 | 24 |
| Example 46 | J-49 | 25 | 2.5 | 77 | 48 |
| Example 47 | J-50 | 27 | 2.5 | 72 | 11 |
| Example 104 | J-104 | 22 | 1.9 | 75 | 5 |
| Example 48 | J-51 | 28 | 2.6 | 74 | 44 |
| Example 49 | J-52 | 28 | 2.7 | 78 | 25 |
| Comparative | CJ-1 | 34 | 3.7 | 64 | 213 |
| Example 1 | | | | | |
| Comparative | CJ-2 | 35 | 4.1 | 64 | 267 |
| Example 2 | | | | | |
| Comparative | CJ-3 | 32 | 4.0 | 65 | 201 |
| Example 3 | | | | | |
| Comparative | CJ-4 | 33 | 3.6 | 62 | 249 |
| Example 4 | | | | | |

As is apparent from the results in Tables 5-1 and 5-2, the radiation-sensitive compositions of the examples were good in sensitivity, CDU, receding contact angle after PB, and number of development defects when used for ArF exposure, whereas the comparative examples were poorer in the characteristics than the examples. Therefore, when the radiation-sensitive compositions of the examples are used for ArF exposure, a resist pattern having good roughness performance, water repellency, and defection performance can be formed with high sensitivity.

### Preparation of Positive Radiation-Sensitive Composition for Extreme Ultraviolet (EUV) Exposure

### Example 50

A radiation-sensitive composition (J-50) was prepared by mixing 100 parts by mass of (A-5) as the first polymer [A], 30.0 parts by mass of (B-7) as the radiation-sensitive acid generator [B], 20.0 parts by mass of (C-4) as the acid diffusion controlling agent [C], 3.0 parts by mass (solid content) of (E-1) as the second polymer [E], and 5,030 parts by mass of a mixed solvent of (D-1)/(D-4) as the solvent [D] and filtering the mixture through a membrane filter having a pore size of 0.2 μm.

### Examples 51 to 66 and Comparative Examples 5 to 7

Radiation-sensitive compositions (J-51) to (J-66) and (CJ-5) to (CJ-7) were prepared in the same manner as in Example 50 except that the components of the types and contents shown in Table 6 below were used.

TABLE 6

| | | First | | Radiation- | | Acid diffusion | | Second | | | | | |
|---|---|---|---|---|---|---|---|---|---|---|---|---|---|
| | | polymer | | sensitive acid | | controlling agent | | polymer | | Other additive | | Solvent | |
| | | [A] | | generator [B] | | [C] | | [E] | | components [W] | | [D] | |
| | Radiation- | | Content | | Content | | Content | | Content | | Content | | Content |
| | sensitive | | (Parts | | (Parts | | (Parts | | (Parts | | (Parts | | (Parts |
| | composition | Type | by mass) | Type | by mass) | Type | by mass) | Type | by mass) | Type | by mass) | Type | by mass) |
| Exam- | J-50 | A-5 | 100 | B-7 | 30.0 | C-4 | 20.0 | E-1 | 3.0 | — | — | D-1/D-2/ | 1000/ |
| ple 50 | | | | | | | | | | | | D-4 | 4000/30 |
| Exam- | J-51 | A-5 | 100 | B-7 | 30.0 | C-4 | 20.0 | E-12 | 3.0 | — | — | D-1/D-2/ | 1000/ |
| ple 51 | | | | | | | | | | | | D-4 | 4000/30 |
| Exam- | J-52 | A-5 | 100 | B-7 | 30.0 | C-4 | 20.0 | E-21 | 3.0 | — | — | D-1/D-2/ | 1000/ |
| ple 52 | | | | | | | | | | | | D-4 | 4000/30 |
| Exam- | J-53 | A-5 | 100 | B-7 | 30.0 | C-4 | 20.0 | E-22 | 3.0 | — | — | D-1/D-2/ | 1000/ |
| ple 53 | | | | | | | | | | | | D-4 | 4000/30 |
| Exam- | J-54 | A-5 | 100 | B-7 | 30.0 | C-4 | 20.0 | E-23 | 3.0 | — | — | D-1/D-2/ | 1000/ |
| ple 54 | | | | | | | | | | | | D-4 | 4000/30 |
| Exam- | J-55 | A-5 | 100 | B-7 | 30.0 | C-4 | 20.0 | E-24 | 3.0 | — | — | D-1/D-2/ | 1000/ |
| ple 55 | | | | | | | | | | | | D-4 | 4000/30 |
| Exam- | J-56 | A-5 | 100 | B-7 | 30.0 | C-4 | 20.0 | E-25 | 3.0 | — | — | D-1/D-2/ | 1000/ |
| ple 56 | | | | | | | | | | | | D-4 | 4000/30 |
| Exam- | J-57 | A-5 | 100 | B-7 | 30.0 | C-4 | 20.0 | E-26 | 3.0 | — | — | D-1/D-2/ | 1000/ |
| ple 57 | | | | | | | | | | | | D-4 | 4000/30 |
| Exam- | J-58 | A-6 | 100 | B-7 | 30.0 | C-4 | 20.0 | E-1 | 3.0 | — | — | D-1/D-2/ | 1000/ |
| ple 58 | | | | | | | | | | | | D-4 | 4000/30 |
| Exam- | J-59 | A-7 | 100 | B-7 | 30.0 | C-4 | 20.0 | E-1 | 3.0 | — | — | D-1/D-2/ | 1000/ |
| ple 59 | | | | | | | | | | | | D-4 | 4000/30 |
| Exam- | J-60 | A-5 | 100 | B-1 | 30.0 | C-4 | 20.0 | E-1 | 3.0 | — | — | D-1/D-2/ | 1000/ |
| ple 60 | | | | | | | | | | | | D-4 | 4000/30 |
| Exam- | J-61 | A-5 | 100 | B-5 | 30.0 | C-4 | 20.0 | E-1 | 3.0 | — | — | D-1/D-2/ | 1000/ |
| ple 61 | | | | | | | | | | | | D-4 | 4000/30 |
| Exam- | J-62 | A-5 | 100 | B-8 | 30.0 | C-4 | 20.0 | E-1 | 3.0 | — | — | D-1/D-2/ | 1000/ |
| ple 62 | | | | | | | | | | | | D-4 | 4000/30 |
| Exam- | J-63 | A-5 | 100 | B-7 | 30.0 | C-2 | 20.0 | E-1 | 3.0 | — | — | D-1/D-2/ | 1000/ |
| ple 63 | | | | | | | | | | | | D-4 | 4000/30 |
| Exam- | J-64 | A-5 | 100 | B-7 | 30.0 | C-3 | 20.0 | E-1 | 3.0 | — | — | D-1/D-2/ | 1000/ |
| ple 64 | | | | | | | | | | | | D-4 | 4000/30 |
| Exam- | J-65 | A-5 | 100 | B-7 | 30.0 | C-4 | 20.0 | E-1 | 3.0 | W-1 | 0.5 | D-1/D-2/ | 1000/ |
| ple 65 | | | | | | | | | | | | D-4 | 4000/30 |
| Exam- | J-66 | A-5 | 100 | B-7 | 30.0 | C-4 | 20.0 | E-1 | 3.0 | W-2 | 0.5 | D-1/D-2/ | 1000/ |
| ple 66 | | | | | | | | | | | | D-4 | 4000/30 |
| Compar- | CJ-5 | A-5 | 100 | B-7 | 30.0 | C-4 | 20.0 | CE-1 | 3.0 | — | — | D-1/D-2/ | 1000/ |
| ative | | | | | | | | | | | | D-4 | 4000/30 |
| Exam- | | | | | | | | | | | | | |
| ple 5 | | | | | | | | | | | | | |
| Compar- | CJ-6 | A-5 | 100 | B-7 | 30.0 | C-4 | 20.0 | CE-2 | 3.0 | — | — | D-1/D-2/ | 1000/ |
| ative | | | | | | | | | | | | D-4 | 4000/30 |
| Exam- | | | | | | | | | | | | | |
| ple 6 | | | | | | | | | | | | | |
| Compar- | CJ-7 | A-5 | 100 | B-7 | 30.0 | C-4 | 20.0 | CE-3 | 3.0 | — | — | D-1/D-2/ | 1000/ |
| ative | | | | | | | | | | | | D-4 | 4000/30 |
| Exam- | | | | | | | | | | | | | |
| ple 7 | | | | | | | | | | | | | |

### <Formation of Resist Pattern Using Positive Radiation-Sensitive Composition for EUN Exposure>

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205 °C for 60 seconds to form an underlayer antireflection film having an average thickness of 105 nm. The positive radiation-sensitive composition for EUV exposure prepared above was applied onto the underlayer antireflection film with use of the spin coater, followed by performing PB at 130 °C for 60 seconds. Thereafter, cooling was performed at 23 °C for 30 seconds to form a resist film having an average thickness of 55 nm. Next, the resist film was exposed by an EUV exposure apparatus (“NXE3300”, manufactured by ASML) with NA of 0.33 under a lighting condition of Conventional s=0.89 and with a mask of imecDEFECT32FFR02. After exposing, PEB was performed at 120 °C for 60 seconds. Thereafter, the resist film was developed with an alkali with use of a 2.38% by mass aqueous TMAH solution as an alkaline developer, followed by washing with water and further drying to form a positive resist pattern (20 nm line-and-space pattern).

### <Evaluation>

The resist patterns formed using the positive radiation-sensitive compositions for EUV exposure were evaluated on sensitivity, LWR, and number of defects after development in accordance with the following methods. The receding contact angle of the resist films before EUV exposure was evaluated according to the following method. The results are shown in Table 7 below. Note that a scanning electron microscope (“CG-5000” manufactured by Hitachi High-Technologies Corporation) was used for measurement of the length of the resist pattern.

### [Sensitivity]

An exposure dose at which a 20 nm line-and-space pattern was formed in the aforementioned resist pattern formation using the positive radiation-sensitive composition for EUV exposure was defined as an optimum exposure dose, and this optimum exposure dose was defined as sensitivity (mJ/cm²). The sensitivity was evaluated to be “good” in a case of being 40 mJ/cm² or less, and “poor” in a case of exceeding 40 mJ/cm².

### [LWR]

A resist pattern was formed by adjusting a mask size so as to form a 20 nm line-and-space pattern by irradiation with the optimum exposure dose obtained in the evaluation of the sensitivity. The formed resist pattern was observed from above the pattern with use of the scanning electron microscope. The variation in the line width was measured at a total of 500 points. The 3 sigma value was obtained from the distribution of the measurement values, and defined as LWR (nm). The smaller the value of the LWR is, the smaller the roughness of the line is, which is better. The LWR was evaluated to be “good” in a case of being 4.0 nm or less, and “poor” in a case of exceeding 4.0 nm.

[Receding Contact Angle after Prebaking (PB)]

The receding contact angle of the resist films before EUV exposure in the method for forming a resist pattern was measured by the following procedure in the environment at a room temperature of 23 °C, a relative humidity of 40%, and normal pressure, using DSA-10 of KRUSS Optronic GmbH.

A 25-μL water drop was formed on the resist film by discharging water through a needle of DSA-10, and then suctioned by the needle at a rate of 10 μL/min for 90 seconds, and the contact angle was measured every second (90 times in total). The average value of a total of 20 contact angles measured from the stabilization of the contact angle in the measurement was calculated and defined as the receding contact angle (°) after PB. When being 70° or more, the receding contact angle after PB was evaluated as “good”, and when less than 70°, evaluated as “poor”.

### [Number of Development Defects]

The resist film was exposed with the optimum exposure dose to form a 20-nm line-and-space pattern and used as a wafer for defect inspection. The number of defects on this wafer for defect inspection was measured with the use of a defect inspection device (“KLA 2810” of KLA-Tencor Corporation). The defects having a diameter of 50 μm or less were determined to be derived from the resist film, and the number of the defects was calculated. When the number of defects determined to be derived from the resist film was 100 or less, the number of defects after development was evaluated as “good”, and when more than 100, evaluated as “poor”.

TABLE 7

| | | Sensi- | | Receding | Number of |
|---|---|---|---|---|---|
| | Radiation- | tivity | | contact angle | development |
| | sensitive | (mJ/ | LWR | after PB | defects |
| | composition | cm²) | (nm) | (°) | (defects) |
| Example 50 | J-50 | 35 | 3.3 | 75 | 43 |
| Example 51 | J-51 | 34 | 3.8 | 77 | 43 |
| Example 52 | J-52 | 36 | 3.3 | 73 | 29 |
| Example 53 | J-53 | 37 | 3.2 | 73 | 25 |
| Example 54 | J-54 | 38 | 3.2 | 72 | 20 |
| Example 55 | J-55 | 37 | 3.6 | 72 | 29 |
| Example 56 | J-56 | 37 | 3.5 | 74 | 37 |
| Example 57 | J-57 | 35 | 3.3 | 77 | 39 |
| Example 58 | J-58 | 37 | 3.0 | 75 | 20 |
| Example 59 | J-59 | 35 | 3.7 | 78 | 40 |
| Example 60 | J-60 | 38 | 3.8 | 75 | 25 |
| Example 61 | J-61 | 37 | 3.5 | 73 | 32 |
| Example 62 | J-62 | 38 | 3.7 | 74 | 15 |
| Example 63 | J-63 | 35 | 3.3 | 78 | 17 |
| Example 64 | J-64 | 37 | 3.4 | 77 | 43 |
| Example 65 | J-65 | 34 | 3.2 | 77 | 32 |
| Example 66 | J-66 | 37 | 3.4 | 78 | 40 |
| Comparative | CJ-5 | 49 | 5.1 | 62 | 389 |
| Example 5 | | | | | |
| Comparative | CJ-6 | 48 | 4.7 | 66 | 307 |
| Example 6 | | | | | |
| Comparative | CJ-7 | 44 | 4.3 | 64 | 335 |
| Example 7 | | | | | |

As is apparent from the results in Table 7, the radiation-sensitive compositions of the examples were good in sensitivity, LWR, receding contact angle after PB, and number of development defects when used for EUV exposure, whereas the comparative examples were poorer in the characteristics than the examples. Therefore, when the radiation-sensitive compositions of the examples are used for EUV exposure, a resist pattern having good water repellency, roughness performance, and defection performance can be formed with high sensitivity.

### Preparation of Negative Radiation-Sensitive Composition for ArF Exposure, and Formation and Evaluation of Resist Pattern Using this Composition

### Example 67

A radiation-sensitive composition (J-67) was prepared by mixing 100 parts by mass of (A-3) as the first polymer [A], 9.0 parts by mass of (B-10) as the radiation-sensitive acid generator [B], 1.0 parts by mass of (C-3) as the acid diffusion controlling agent [C], 2.0 parts by mass (solid content) of (E-26) as the second polymer [E], and 3,230 parts by mass of a mixed solvent of (D-1)/(D-2)/(D-3) (mass ratio: 2,240 parts/960 parts/30 parts) as the solvent [D] and filtering the mixture through a membrane filter having a pore size of 0.2 μm.

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205 °C for 60 seconds to form an underlayer antireflection film having an average thickness of 100 nm. The negative radiation-sensitive composition for ArF exposure (J-67) prepared above was applied onto the underlayer antireflection film with use of the spin coater, followed by performing PB (pre-baking) at 100 °C for 60 seconds. Thereafter, cooling was performed at 23 °C for 30 seconds to form a resist film having an average thickness of 150 nm. Next, this resist film was exposed through a mask pattern having a hole of 60 nm and a pitch of 120 nm using an ArF excimer laser immersion exposure apparatus (“TWINSCAN XT-1900i” manufactured by ASML) with NA of 1.35 under an optical condition of Annular (σ=0.8/0.6). After the exposure, PEB (post exposure baking) was performed at 100 °C for 60 seconds. Thereafter, the resist film was developed with an organic solvent using n-butyl acetate as an organic solvent developer, and dried to form a negative resist pattern (contact hole pattern with hole of 60 nm and pitch of 120 nm).

The resist pattern and resist film before ArF exposure formed using the negative radiation-sensitive composition for ArF exposure were evaluated in terms of the sensitivity, CDU, receding contact angle after PB, and number of defects after development in the same manner as in the evaluation of the resist patterns formed using the positive radiation-sensitive compositions for ArF immersion exposure. As a result, when forming a negative resist pattern by ArF exposure, the radiation-sensitive composition of Example 67 gave high sensitivity and good CDU, receding contact angle after PB, and number of defects after development.

### Preparation of Negative Radiation-Sensitive Composition for EUV Exposure, and Formation and Evaluation of Resist Pattern using this composition

### Example 68

A radiation-sensitive composition (J-68) was prepared by mixing 100 parts by mass of (A-6) as the first polymer [A], 35.0 parts by mass of (B-11) as the radiation-sensitive acid generator [B], 25.0 parts by mass of (C-4) as the acid diffusion controlling agent [C], 2.0 parts by mass (solid content) of (E-26) as the second polymer [E], and 6,110 parts by mass of a mixed solvent of (D-1)/(D-2) (mass ratio: 4,280 parts/1,830 parts) as the solvent [D] and filtering the mixture through a membrane filter having a pore size of 0.2 μm.

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205 °C for 60 seconds to form an underlayer antireflection film having an average thickness of 105 nm. The negative radiation-sensitive composition for EUV exposure (J-68) prepared above was applied onto the underlayer antireflection film with use of the spin coater, followed by performing PB at 130 °C for 60 seconds. Thereafter, cooling was performed at 23 °C for 30 seconds to form a resist film having an average thickness of 62 nm. Next, the resist film was exposed by an EUV exposure apparatus (“NXE3300”, manufactured by ASML) with NA of 0.33 under a lighting condition of Conventional s=0.89 and with a mask of imecDEFECT32FFR15. After exposing, PEB was performed at 120 °C for 60 seconds. Thereafter, the resist film was developed with an organic solvent using n-butyl acetate as an organic solvent developer, and dried to form a negative resist pattern (24 nm line-and-space pattern).

The resist pattern using the negative radiation-sensitive composition for EUV exposure was evaluated in the same manner as in the evaluation of the resist pattern using the positive radiation-sensitive composition for EUV exposure. As a result, when forming a negative resist pattern by EUV exposure, the radiation-sensitive composition of Example 68 gave high sensitivity and good LWR, receding contact angle after PB, and number of defects after development.

### [Preparation of Composition for Forming Liquid Immersion Upper Film for ArF Immersion Exposure, Preparation of Positive Radiation-Sensitive Composition for ArF Immersion Exposure, And Formation and Evaluation of Resist Pattern Using these Compositions]

### Example 106-TC

A composition (J-106-TC) for forming a liquid immersion upper film was prepared by mixing 100 parts by mass (solid content) of (E-24) as the polymer (second polymer) [E] for forming a liquid immersion upper film and 4,000 parts by mass of a mixed solvent of 4-methyl-2-pentanol/diisoamyl ether (mass ratio: 3,000 parts/1,000 parts) as the solvent [D] and filtering the mixture through a membrane filter having a pore size of 0.2 μm.

### Example 106-PR

A radiation-sensitive composition (J-106-PR) was prepared by mixing 100 parts by mass of (A-1) as the first polymer [A], 6.0 parts by mass of (B-12) as the radiation-sensitive acid generator [B], 2.0 parts by mass of (C-5) as the acid diffusion controlling agent [C], and 3,230 parts by mass of a mixed solvent of (D-1)/(D-2)/(D-3) (mass ratio: 2,240 parts/960 parts/30 parts) as the solvent [D] and filtering the mixture through a membrane filter having a pore size of 0.2 μm.

Onto the surface of an 8-inch silicon wafer, an underlayer antireflection film forming composition (“ARC66” manufactured by Brewer Science, Inc.) was applied with the use of a spin coater (“CLEAN TRACK ACT8” manufactured by Tokyo Electron Ltd.). The wafer was then heated at 205 °C for 60 seconds to form an underlayer antireflection film having an average thickness of 75 nm. The positive radiation-sensitive composition (J-106-PR) for ArF exposure prepared above was applied onto the underlayer antireflection film with the use of the spin coater, followed by performing PB (prebaking) at 100 °C for 60 seconds. Thereafter, cooling was performed at 23 °C for 30 seconds to form a resist film having an average thickness of 250 nm. Thereafter, the composition (J-106-TC) for forming a liquid immersion upper film prepared above was applied onto the resist film with the use of the spin coater, followed by performing PB (prebaking) at 100 °C for 20 seconds. Thereafter, cooling was performed at 23 °C for 30 seconds to form a liquid immersion upper film having an average thickness of 30 nm. Next, this resist film was exposed through a mask pattern of contact holes with a 100 nm hole and a 200 nm pitch using an ArF excimer laser immersion exposure apparatus (“TWINSCAN XT-1900i” manufactured by ASML) at NA=1.35 under an optical condition of Dipole (σ=0.8/0.6). After the exposure, PEB (post exposure baking) was performed at 100 °C for 60 seconds. Thereafter, the resist film was developed with an alkali with the use of a 2.38-mass % aqueous TMAH solution as an alkaline developer, followed by washing with water and further drying to form a positive resist pattern (pattern of contact holes with a 100 nm hole and a 200 nm pitch).

The sensitivity, CDU, receding contact angle after PB, and number of defects after development were evaluated in the same manner as the evaluation of the resist pattern formed using the positive radiation-sensitive composition for ArF exposure. As a result, when forming a liquid immersion upper film using the composition for forming a liquid immersion upper film containing the second polymer and forming the positive resist pattern by ArF immersion exposure, high sensitivity and good CDU, receding contact angle after PB, and number of defects after development were obtained.

According to the radiation-sensitive composition, composition for forming a liquid immersion upper film, method for forming a pattern, and compound of the present disclosure, a resist pattern having good sensitivity to exposure light and having CDU, LWR, water repellency, and less defects can be formed. Therefore, the compositions, method, and compound can be suitably used for a machining process and the like of a semiconductor device that is expected to be further miniaturized in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
a first polymer comprising a structural unit (I) which comprises an acid-dissociable group;
a second polymer comprising a structural unit (i) derived from a compound represented by formula (F1); and
a solvent: 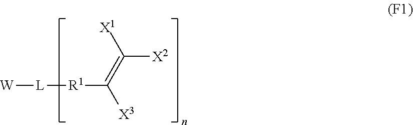
wherein, in the formula (F1),
W is a polymerizable group,
L is a single bond or an (n+1)-valent linking group,
R¹ is a divalent hydrocarbon group having 1 to 10 carbon atoms,
X¹, X², and X³ are each independently a hydrogen atom or a fluorine atom, at least one selected from the group consisting of X¹, X², and X³ is a fluorine atom,
n is an integer of 1 to 3, n is 1 when L is a single bond, and a plurality of R¹s, X¹s, X²s, or X³s are same as or different from each other when n is 2 or more.

2. The radiation-sensitive composition according to claim 1, wherein the compound is represented by formula (f1-1) or (f1-2): 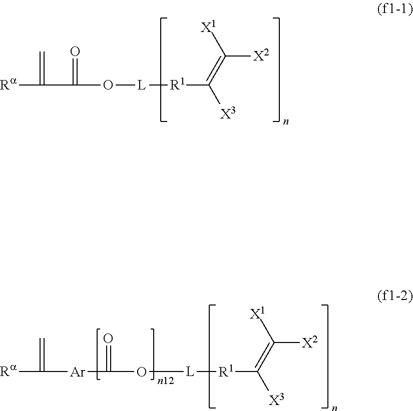
wherein, in the formulas (f1-1) and (f1-2),
R^{α} is a hydrogen atom, a halogen atom, or a monovalent organic group having 1 to 10 carbon atoms,
L, R¹, X¹, X², X³, and n are each as defined in the formula (F1), n is 1 when L¹¹ is a single bond, and
in the formula (f1-2),
Ar is a substituted or unsubstituted divalent aromatic ring, and
n₁₂ is 0 or 1.

3. The radiation-sensitive composition according to claim 1, wherein R¹ is a divalent hydrocarbon group having one or two carbon atoms.

4. The radiation-sensitive composition according to claim 1, wherein X¹, X², and X³ are each a fluorine atom.

5. The radiation-sensitive composition according to claim 2, wherein Ar is a benzene ring or a naphthalene ring.

6. The radiation-sensitive composition according to claim 1, wherein a content ratio of the structural unit (i) in the second polymer to all structural units constituting the second polymer is 5 mol % or more and 100 mol % or less.

7. The radiation-sensitive composition according to claim 1, wherein a content of the second polymer in the radiation-sensitive composition is 0.01 parts by mass or more and 30 parts by mass or less based on 100 parts by mass of the first polymer.

8. The radiation-sensitive composition according to claim 1, wherein the structural unit which comprises an acid-dissociable group is represented by formula (3): 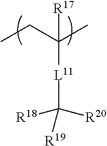
wherein, in the formula (3),
R¹⁷ is a hydrogen atom, a fluorine atom, a methyl group, or a trifluoromethyl group,
R¹⁸ is a monovalent hydrocarbon group having 1 to 20 carbon atoms,
R¹⁹ and R²⁰ are each independently a monovalent chain hydrocarbon group having 1 to 10 carbon atoms or a monovalent alicyclic hydrocarbon group having 3 to 20 carbon atoms, or R¹⁹ and R²⁰ taken together represent a divalent alicyclic group having 3 to 20 carbon atoms together with the carbon atom to which R¹⁹ and R²⁰ are bonded,
L¹¹ represents *—COO—, *—L^{11a}COO—, or *—COOL^{11a}COO—, L^{11a} is a substituted or unsubstituted alkanediyl group or arenediyl group, and*is a bond with the carbon atom to which R¹⁷ is bonded.

9. The radiation-sensitive composition according to claim 1, wherein the first polymer further comprises a structural unit comprising at least one selected from the group consisting of a lactone structure, a cyclic carbonate structure, and a sultone structure.

10. The radiation-sensitive composition according to claim 1, wherein the first polymer further comprises a structural unit comprising a phenolic hydroxy group.

11. The radiation-sensitive composition according to claim 1 2, further comprising a radiation-sensitive acid generator.

12. The radiation-sensitive composition according to claim 1, further comprising an acid diffusion controlling agent.

13. A method for forming a pattern comprising:
applying the radiation-sensitive composition according to claim 1 directly or indirectly to a substrate to form a resist film;
exposing the resist film to light; and
developing the exposed resist film.

14. The method for forming a pattern according to claim 13, wherein exposing comprises exposing the resist film to a g-line, an i-line, a KrF excimer laser, an ArF excimer laser, or an extreme ultraviolet ray.

15. A composition comprising:
a second polymer comprising a structural unit (i) derived from a compound represented by formula (F1); and
a solvent: 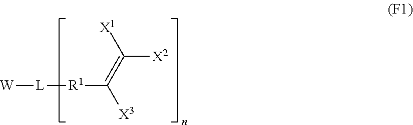
wherein, in the formula (F1),
W is a polymerizable group,
L is a single bond or an (n+1)-valent linking group,
R¹ is a divalent hydrocarbon group having 1 to 10 carbon atoms,
X¹, X², and X³ are each independently a hydrogen atom or a fluorine atom, at least one selected from the group consisting of X¹, X², and X³ is a fluorine atom,
n is an integer of 1 to 3, n is 1 when L is a single bond, and a plurality of R¹s, X¹s, X²s, or X³s are same as or different from each other when n is 2 or more.

16. The composition according to claim 15, wherein the compound is represented by formula (f1-1) or (f1-2): 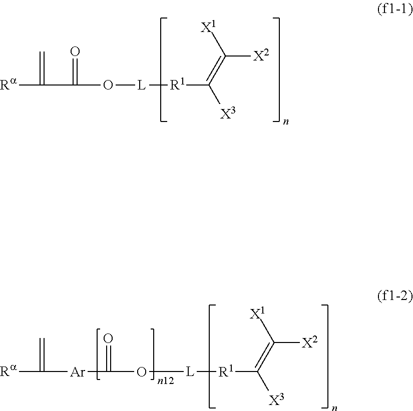
wherein, in the formulas (f1-1) and (f1-2),
R^{α} is a hydrogen atom, a halogen atom, or a monovalent organic group having 1 to 10 carbon atoms,
L, R¹, X¹, X², X³, and n are each as defined in the formula (F1), n is 1 when L¹¹ is a single bond, and
in the formula (f1-2),
Ar is a substituted or unsubstituted divalent aromatic ring, and
n₁₂ is 0 or 1.

17. A method for forming a pattern comprising:
directly or indirectly applying a radiation-sensitive composition to a substrate to form a resist film;
applying the composition according to claim 15 to the resist film to form a liquid immersion upper film;
subjecting the resist film provided with the liquid immersion upper film to immersion exposure; and
developing the resist film subjected to the immersion exposure.

18. A compound comprising: a polymerizable group; and a partial structure represented by formula (a): 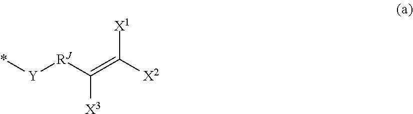
wherein, in the formula (a),
Y is a divalent heteroatom-containing group or a divalent linking group having three or more carbon atoms,
R^{J} is a divalent hydrocarbon group having one or two carbon atoms,
X¹, X², and X³ are each independently a hydrogen atom or a fluorine atom, at least one selected from the group consisting of X¹, X², and X³ is a fluorine atom, and
* is a bond to an atom of a portion other than the partial structure in the compound.

19. The compound according to claim 18, represented by a formula (A-1) or (A-2): 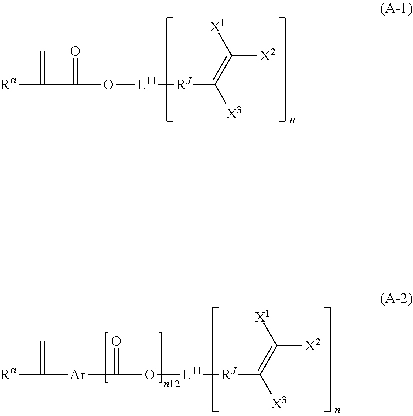
wherein, in the formulas (A-1) and (A-2),
R^{α} is a hydrogen atom, a halogen atom, or a monovalent organic group having 1 to 10 carbon atoms,
L¹¹ is a single bond, an (n+1)-valent linking group having 1 or more carbon atoms and comprising a heteroatom, or an (n+1)-valent linking group having 3 or more carbon atoms,
n is an integer of 1 to 3, n is 1 when L¹¹ is a single bond,
R^{J}, X¹, X², and X³ are each as defined in the formula (a), a plurality of RJs, X¹s, X²s, and X³s are same as or different from each other when n is 2 or more, and
in the formula (A-2),
Ar is a substituted or unsubstituted divalent aromatic ring, and
n₁₂ is 0 or 1.

20. The compound according to claim 18, wherein X¹, X², and X³ are each a fluorine atom.
